(19) United States
(12) Patent Application Publication
(10) Pub. No.: US 2025/0286003 A1
(43) Pub. Date: Sep. 11, 2025

(54) DISPLAY DEVICE AND METHOD OF MANUFACTURING THE SAME

(71) Applicant: Samsung Display Co., Ltd., Yongin-si (KR)

(72) Inventors: Hae Yun CHOI, Yongin-si (KR); Joo Woan CHO, Yongin-si (KR); Byeong Hwa CHOI, Yongin-si (KR); Jae Ho CHOI, Yongin-si (KR); Hye Jung HONG, Yongin-si (KR)

(73) Assignee: Samsung Display Co., Ltd., Yongin-si (KR)

(21) Appl. No.: 18/938,608

(22) Filed: Nov. 6, 2024

(30) Foreign Application Priority Data
Mar. 11, 2024 (KR) 10-2024-0033848

(51) Int. Cl. H01L 23/00; H01L 21/66; H01L 25/075; H01L 33/62

(52) U.S. Cl. CPC H01L 24/08; H01L 22/32; H01L 25/0753; H01L 24/16; H01L 2224/08238; H01L 2224/16227; H01L 2924/12041; H10H 20/857

(57) ABSTRACT

A display device includes a first panel pad area on a non-display area of a substrate, first panel pads on the first panel pad area and spaced apart from one another along a first direction, second panel pads spaced apart from the first panel pads in a second direction and spaced apart from one another along the first direction, a planarization layer on the first and second panel pads and including contact holes exposing corresponding ones of the first panel pads, upper pad electrodes on the planarization layer and electrically connected to corresponding ones of the first panel pads via corresponding ones of the contact holes, a circuit board overlapping the first panel pad area in a third direction and including circuit pads, and an anisotropic conductive film on the first panel pad area and electrically connecting the upper pad electrodes to corresponding ones of the circuit pads.

### CROSS-REFERENCE TO RELATED APPLICATION(S)

This U.S. non-provisional patent application claims priority to and the benefits of Korean Patent Application No. 10-2024-0033848 under 35 U.S.C. § 119, filed in the Korean Patent Intellectual Property Office on Mar. 11, 2024, the entire contents of which are hereby incorporated by reference.

### BACKGROUND

### 1. Technical Field

The disclosure generally relates to a display device and a method of manufacturing the same.

### 2. Description of the Related Art

As the information society develops, demands for display devices for displaying images are increasing in various forms. For example, display devices may be applied to (or in association with) various electronic devices, such as smartphones, digital cameras, notebook computers, navigation devices, smart televisions, billboards, appliances, etc.

The display devices may be flat panel display devices, such as liquid crystal display devices, field emission display devices, and light emitting display devices. The light emitting display devices may include an organic light emitting display device including an organic light emitting element, an inorganic light emitting display device including an inorganic light emitting element, such as an inorganic semiconductor, and a micro-light emitting display device including a micro-light emitting element,

A head-mounted display including a light emitting display device has been developed. The head-mounted display may be a virtual reality (VR), augmented reality (AR), or mixed reality (MR) glasses-type monitor device that may be worn in the form of glasses, goggles, or a helmet and may form a focus at a relatively short distance in front of a user's eyes. A high-resolution micro-light emitting diode display panel including a micro-light emitting diode element may be applied to the head-mounted display.

The background provided herein is for the purpose of generally presenting the context of the disclosure. Work of the presently named inventors, to the extent that it is described in this background section, as well as aspects of the description that may not otherwise qualify as prior art at the time of filing, are neither expressly nor impliedly admitted as prior art against the disclosure.

### SUMMARY

Some aspects provide a display device capable of increasing the degree of freedom in a process of connecting a display panel and a circuit board together, and that can be used to implement a relatively high-resolution display device.

Some aspects provide a method of manufacturing a display device capable of increasing the degree of freedom in a process of connecting a display panel and a circuit board and that can implement a relatively high-resolution display device.

Additional aspects will be set forth in the detailed description, which follows, and in part, will be apparent from the disclosure, or may be learned by practice of the disclosed embodiments and/or the claimed subject matter.

According to an aspect, a display device includes a substrate, a first panel pad area, first panel pads, second panel pads, a planarization layer, upper pad electrodes, a circuit board, and an anisotropic conductive film. The substrate includes a display area and a non-display area. The first panel pad area is disposed on the non-display area. The first panel pads are disposed on the first panel pad area. The first panel pads are spaced apart from one another along a first direction. The second panel pads are spaced apart from the first panel pads in a second direction transverse to the first direction. The second panel pads are spaced apart from one another along the first direction. The planarization layer is disposed on the first panel pads and the second panel pads. The planarization layer includes contact holes. Each contact hole exposes a corresponding first panel pad among the first panel pads. The upper pad electrodes are disposed on the planarization layer. Each upper pad electrode among the upper pad electrodes is electrically connected to a corresponding first panel pad among the first panel pads via a corresponding contact hole among the contact holes. The circuit board overlaps the first panel pad area in a third direction perpendicular to the first direction and the second direction. The circuit board includes circuit pads. The anisotropic conductive film is disposed on the first panel pad area and electrically connects each upper pad electrode among the upper pad electrodes to a corresponding circuit pad among the circuit pads.

In an embodiment, the upper pad electrodes may include a first upper pad electrode and a second upper pad electrode spaced apart from the first upper pad electrode in the first direction.

In an embodiment, the first upper pad electrode may overlap one first panel pad in the third direction among the first panel pads, and the second upper pad electrode may overlap another first panel pad in the third direction among the first panel pads. The another first panel pad may be adjacent to the one first panel pad.

In an embodiment, the first upper pad electrode may overlap two second panel pads in the third direction among the second panel pads. The two second panel pads may be adjacent to the one first panel pad. The second upper pad electrode may not overlap the second panel pads in the third direction.

In an embodiment, the first upper pad electrode may be disposed closer to the display area than the second upper pad electrode.

In an embodiment, respective widths of the upper pad electrodes may be greater than corresponding widths of the first panel pads or corresponding widths of the second panel pads.

In an embodiment, the first panel pads and the upper pad electrodes may be arranged in one-to-one correspondence with each other.

In an embodiment, each of the upper pad electrodes may include a first part having a first width and a second part having a second width. The first width may be smaller than the second width.

In an embodiment, the upper pad electrodes may include a first upper pad electrode and a second upper pad electrode. A direction in which the first part of the first upper pad electrode protrudes from the second part of the first upper pad electrode may be opposite a direction in which the first part of the second upper pad electrode protrudes from the second part of the second upper pad electrode.

In an embodiment, the direction in which the first part of the first upper pad electrode protrudes from the second part of the first upper pad electrode may be a direction extending toward an adjacent side of the substrate. The direction in which the first part of the second upper pad electrode protrudes from the second part of the second upper pad electrode may be a direction extending toward the display area.

In an embodiment, the first upper pad electrode may overlap one first panel pad in the third direction among the first panel pads. The first upper pad electrode may overlap two second panel pads in the third direction among the second panel panels. The two second panel pads may be adjacent to the one first panel pad. The second upper pad electrode may not overlap the second panel pads in the third direction.

According to an aspect, a display device includes a substrate, a first panel pad area, first panel pads, second panel pads, a planarization layer, upper pad electrodes, a circuit board, and an anisotropic conductive film. The substrate includes a display area and a non-display area. The first panel pad area is disposed on the non-display area. The first panel pads are disposed on the first panel pad area. The first panel pads are spaced apart from one another along a first direction. The second panel pads are spaced apart from the first panel pads in a second direction transverse to the first direction. The second panel pads are spaced apart from one another along the first direction. The planarization layer is disposed on the second panel pads. The upper pad electrodes are disposed on the first panel pads. The circuit board overlaps the first panel pad area in a third direction perpendicular to the first direction and the second direction. The circuit board includes circuit pads. The anisotropic conductive film is disposed on the first panel pad area and electrically connects each upper pad electrode among the upper pad electrodes to a corresponding circuit pad among the circuit pads.

In an embodiment, the planarization layer may overlap the second panel pads in the third direction and may not overlap the first panel pads in the third direction.

In an embodiment, each of the upper pad electrodes may directly contact a corresponding first panel pad among the first panel pads.

In an embodiment, the upper pad electrodes may include a first upper pad electrode and a second upper pad electrode spaced apart from the first upper pad electrode in the first direction.

In an embodiment, the first upper pad electrode may overlap the planarization layer in the third direction, and the second upper pad electrode may not overlap the planarization layer in the third direction.

According to an aspect, a method of manufacturing a display device includes forming, on a substrate, first panel pads spaced apart from one another along a first direction, and second panel pads spaced apart from the first panel pads in a second direction transverse to the first direction. The second panel pads are spaced apart from one another along the first direction. The method further includes forming a planarization layer on the second panel pads or both the first panel pads and the second panel pads, forming upper pad electrodes on at least the planarization layer, each upper pad electrode among the upper pad electrodes being electrically connected to a corresponding first panel pad among the first panel pads. The method further includes aligning circuit pads of a circuit board with the upper pad electrodes, and compressing an anisotropic conductive film between the circuit board and the substrate to bond the circuit board and the substrate together and to form respective electrical connections between the upper pad electrodes and the circuit pads.

In an embodiment, the planarization layer may be formed on both the first panel pads and the second panel pads. The method may further include forming contact holes in the planarization layer. Each contact hole among the contact holes may expose a corresponding first panel pad among the first panel pads. The method may further include forming connection electrodes in the contact holes. Each connection electrode may be formed in a corresponding contact hole among the contact holes. Each upper pad electrode among the upper pad electrodes may be electrically connected to a corresponding first panel pad among the first panel pads through a corresponding connection electrode among the connection electrodes.

In an embodiment, in a view in a third direction perpendicular to the first direction and the second direction, the planarization layer may not overlap the first panel pads. Each upper pad electrode among the upper pad electrodes may be further formed directly on a portion of a corresponding first panel pad among the first panel pads to form an electrical connection between that upper pad electrode and the corresponding first panel pad.

In an embodiment, the method may further include forming, on the substrate, test pads from a same layer of material used to form the first panel pads. Each test pad may be electrically connected to a corresponding first panel pad among the first panel pads. The method may further include forming test electrodes on the test pads from a same layer of material used to form the upper pad electrodes, and cutting the substrate into at least one cell. Cutting the substrate into at least one cell may separate the test pads and the test electrodes from the display device.

According to various embodiments, adhesion reliability can be improved between a circuit board and a substrate by increasing the area of adhesion between an anisotropic conductive film and an upper pad electrode. In some implementations, a relatively high-resolution display device in which a pad area and a circuit board are bonded together using an anisotropic conductive film may be implemented.

According to some embodiments, at least because a planarization layer may be formed not to overlap a first panel pad and to overlap a second panel pad, it may be possible to omit one or more contact holes in the planarization layer, thereby simplifying the structure and omitting one or more manufacturing processes.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals and/or characters refer to similar elements.

FIG. 1 is a schematic plan view of a display device according to an embodiment.

FIG. 2 is a schematic cross-sectional view taken along sectional line Q1-Q1′ of FIG. 1 according to an embodiment.

FIG. 3 is a schematic cross-sectional view of a light emitting element according to an embodiment.

FIG. 4 is an enlarged, schematic plan view of part P1 of FIG. 1 according to an embodiment.

FIG. 5 is a schematic cross-sectional view taken along sectional line Q2-Q2′ of FIG. 4 according to an embodiment.

FIG. 6 is a schematic cross-sectional view taken along sectional line Q3-Q3′ of FIG. 4 according to an embodiment.

FIG. 7 is an enlarged, schematic plan view of an example of part P1 of FIG. 1 according to an embodiment.

FIG. 8 is a schematic plan view illustrating first upper pad electrodes and a second upper pad electrode of FIG. 7 according to an embodiment.

FIG. 9 is an enlarged, schematic plan view of an example of part P1 of FIG. 1 according to an embodiment.

FIG. 10 is a schematic cross-sectional view taken along sectional line Q4-Q4′ of FIG. 9 according to an embodiment.

FIG. 11 is a schematic cross-sectional view taken along sectional line Q5-Q5′ of FIG. 9 according to an embodiment.

FIGS. 12 through 18 are schematic cross-sectional views of a display device at various stages of manufacture according to an embodiment.

FIG. 19 is a schematic perspective view of a virtual reality (VR) device including a display device according to an embodiment.

FIG. 20 is a schematic perspective view of a smart device including a display device according to an embodiment.

FIG. 21 is a schematic perspective view of a vehicle including a display device according to an embodiment.

FIG. 22 is a schematic perspective view of a transparent display device including a display device according to an embodiment.

### DETAILED DESCRIPTION OF THE EMBODIMENTS

In the following description, for the purposes of explanation, numerous specific details are set forth to provide a thorough understanding of various embodiments or implementations. The terms “embodiments” and “implementations” may be used interchangeably to describe one or more non-limiting examples of systems, apparatuses, methods, etc., described herein. It is apparent, however, that various embodiments may be practiced without these specific details or with one or more equivalent arrangements. In other instances, known structures and devices are shown in block diagram form to avoid unnecessarily obscuring various embodiments. Further, various embodiments may be different, but do not have to be exclusive. For example, specific shapes, configurations, and characteristics of an embodiment may be used or implemented in another embodiment without departing from the teachings of the disclosure.

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure.

The use of cross-hatching and/or shading in the accompanying drawings is generally provided to clarify boundaries between adjacent elements. As such, neither the presence nor the absence of cross-hatching or shading is intended to convey or indicate any preference or requirement for materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. In a case that an embodiment may be implemented differently, a specific process order may be performed differently from the described order. For example, two consecutively described processes may be performed substantially at the same time or performed in an order opposite the described order. Also, like reference numerals and/or reference characters denote like elements.

In a case that an element, such as a layer, is referred to as being “on,” “over,” “connected to (or with),” or “coupled to (or with)” another element, it may be directly on, directly over, directly connected to (or with), or directly coupled to (or with) the other element or at least one intervening element may be present. However, in a case that an element is referred to as being “directly on,” “directly over,” “directly connected to (or with),” or “directly coupled to (or with)” another element, there are no intervening elements present. Other terms and/or phrases, if used herein, to describe a relationship between elements should be interpreted in a like fashion, such as “between” versus “directly between,” “adjacent” versus “directly adjacent,” “on” versus “directly on,” “contacting” versus “directly contacting,” “touching” versus “directly touching,” etc. Further, the term “connected” may refer to physical, electrical, and/or fluid connection. To this end, for the purposes of this disclosure, the phrase “fluidically connected” may be used with respect to volumes, plenums, holes, openings, etc., that may be connected to one another, either directly or via one or more intervening components or volumes, to form a fluidic connection, similar to how the phrase “electrically connected” is used with respect to components that are connected to form an electric connection.

For the purposes of this disclosure, a first axis extending along a first direction DR1, a second axis extending along a second direction DR2, and a third axis extending along a third direction DR3 are not limited to three axes of a rectangular coordinate system, such as x, y, and z axes of a Cartesian coordinate system, and may be interpreted in a broader sense. For example, the first axis, the second axis, and the third axis may be perpendicular to one another, or may represent different directions that are not perpendicular to one another. Further, if used herein, the phrases “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. Also, if used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.”

Spatially relative terms, such as “beneath,” “below,” “under,” “lower,” “above,” “upper,” “over,” “higher,” “side” (e.g., as in “sidewall”), and the like, may be used herein for descriptive purposes, and thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and as such, the spatially relative descriptors used herein interpreted accordingly.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in and of itself, as necessarily encompassing a plurality of items-it is to be understood that a set or a subset can encompass only one member or multiple members (unless the context indicates otherwise).

The terms “comprises,” “comprising,” “includes,” “including,” “has,” “have,” and/or “having” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” “approximately,” and other similar terms, are used as terms of approximation and not as terms of degree, and as such, are utilized to account for inherent deviations in measured, calculated, and/or provided values that would be recognized by one of ordinary skill in the art. Accordingly, the term “substantially,” if used herein, and unless otherwise specified, may mean within 5% of a referenced value. For example, substantially perpendicular may mean within ±5% of being parallel. Moreover, the term “between,” if used herein in association with a range of values, is to be understood, unless otherwise indicated, as being inclusive of the start and end values of the range. For example, between 1 and 5 is to be understood as being inclusive of the numbers 1, 2, 3, 4, and 5, not just the numbers 2, 3, and 4.

Various embodiments are described herein with reference to sectional views, isometric views, perspective views, orthographic views, and/or exploded illustrations that are schematic depictions of idealized embodiments and/or intermediate structures. As such, variations from the shapes of the illustrations because of, for example, manufacturing techniques and/or tolerances, are to be expected. Thus, embodiments disclosed herein should not be construed as limited to the illustrated shapes of regions, but are to include deviations in shapes that result from, for instance, manufacturing. To this end, regions illustrated in the drawings may be schematic in nature and shapes of these regions may not reflect the actual shapes of regions of a device, and as such, are not intended to be limiting.

As customary in the field, some embodiments may be described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and are not to be interpreted in an idealized or overly formal sense, unless expressly so defined herein.

Hereinafter, various embodiments will be described with reference to the accompanying drawings.

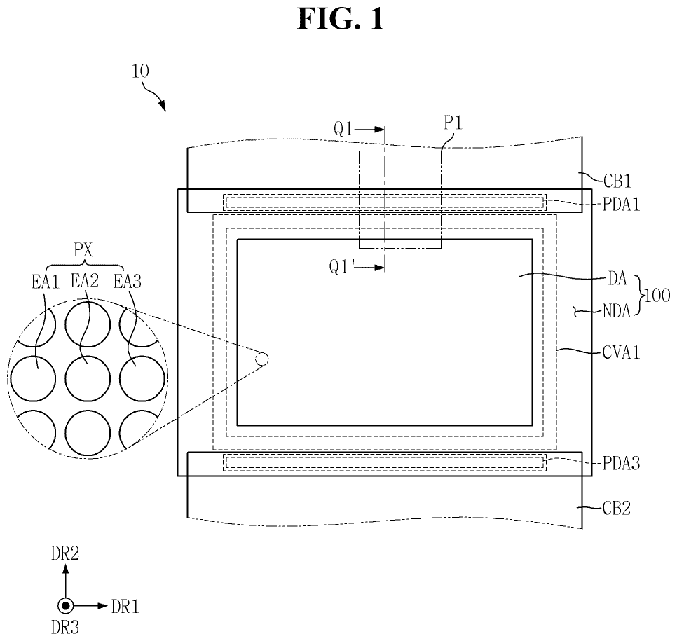

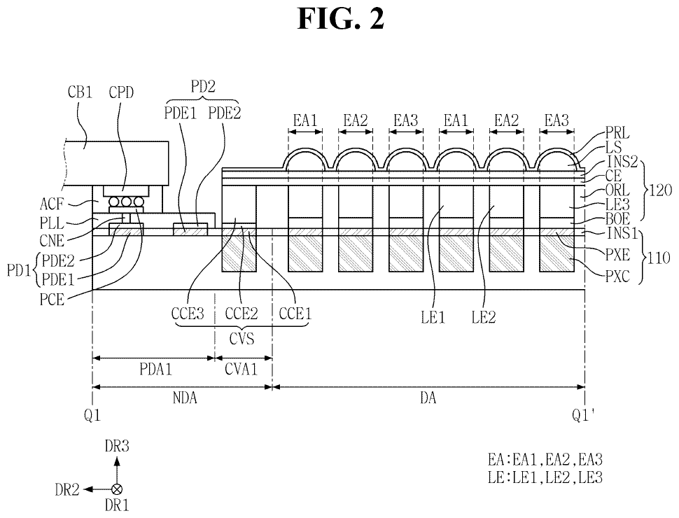

FIG. 1 is a schematic plan view of a display device 10 according to an embodiment. FIG. 2 is a schematic cross-sectional view taken along sectional line Q1-Q1′ of FIG. 1 according to an embodiment.

FIGS. 1 and 2 schematically show an embodiment in which the display device 10 is a light emitting diode on silicon (LEDoS) display device in which light emitting diodes are disposed as light emitting elements LE on a semiconductor circuit board formed by a semiconductor process using a silicon wafer (e.g., on a substrate 110 (e.g., a backplane substrate) of a display panel 100 in which pixel circuits PXC, etc., are formed on a silicon wafer). However, a device including the light emitting elements LE is not limited to the above example. For example, the light emitting elements LE may be applied to (or in association with) a display device of a different type and/or structure, or may be applied to a device of a different type and/or structure, such as a lighting device, e.g., a lightbulb. Hereinafter, substrate 110 will be referred to as backplane substrate 110.

In FIGS. 1 and 2, a first direction DR1 may refer to a horizontal direction of the display panel 100, and a second direction DR2 may refer to a vertical direction of the display panel 100. A third direction DR3 may refer to a thickness direction of the display panel 100. In this manner, a “plan view” may be a view of the display panel 100 in the third direction DR3.

The display device 10 according to an embodiment may include the display panel 100. The display panel 100 may include a display area DA and a non-display area NDA.

The display panel 100 may have a quadrilateral planar shape with long sides in the first direction DR1 and short sides in the second direction DR2. However, the planar shape of the display panel 100 is not limited to this example, and the display panel 100 may have a polygonal, circular, oval, elliptical, or irregular planar shape other than or in addition to the quadrilateral planar shape. As used herein, a “planar shape” may refer to the shape of an element in a view (e.g., a plan view) in the third direction DR3 of that element.

The display area DA may be an area where an image can be displayed, and the non-display area NDA may be an area where no image is displayed. In an embodiment, the planar shape of the display area DA may follow (or correspond with) the planar shape of the display panel 100, but embodiments are not limited to this example. For instance, the planar shape of the display area DA may be different from the planar shape of the display panel 100. As shown in FIG. 1, the planar shape of the display area DA is a quadrilateral planar shape. The display area DA may be disposed in a central area (or region) of the display panel 100. The non-display area NDA may be disposed outside (e.g., around) the display area DA. For example, the non-display area NDA may surround the display area DA in a view in the third direction DR3. For instance, an inner boundary of the non-display area NDA may encircle (or circumscribe) an outer boundary of the display area DA in a view in the third direction DR3. As used herein, the terms “encircle” and “circumscribe” are not limited to a first feature forming a circle around a second feature, and as such, may include the first feature forming any suitable two-dimensional geometric figure around the second feature in a view in, for instance, the third direction DR3. To this end, a first feature encircling or circumscribing a second feature may (unless otherwise specified) include an inner boundary of the first feature touching one or more points of an outer boundary of the second feature, or the inner boundary of the first feature may be spaced apart from the outer boundary of the second feature.

The display area DA of the display panel 100 may include pixels PX. Each of the pixels PX may be defined as (or form) a minimum light emitting unit (or structure) that can display a color of light, such as white light. In some implementations, a single pixel PX may be configured to display white light, and thereby, form a minimum light emitting unit. In some embodiments, two or more sub-pixels may together form a single pixel PX configured to display white light as a group, and thereby, together form a minimum light emitting unit.

In an embodiment, each of the pixels PX may include three light emitting elements LE. For example, each of the pixels PX may include a first light emitting element LE1 disposed in a first emission area EA1, a second light emitting element LE2 disposed in a second emission area EA2, and a third light emitting element LE3 disposed in a third emission area EA3. Hereinafter, the first light emitting element LE1, the second light emitting element LE2, and the third light emitting element LE3 may be collectively (or individually) referred to as light emitting elements LE. The number and/or type of light emitting elements LE provided in (or as part of) each of the pixels PX may vary according to embodiments.

In an embodiment, each of the pixels PX may include light emitting elements LE, which emit light of different colors from one another. For example, the first light emitting element LE1, the second light emitting element LE2, and the third light emitting element LE3 may emit light of different colors from one another.

The first light emitting element LE1 may emit first light. The first light may be red light. For example, a peak wavelength (R-peak) of the first light may be in a range of about 600 nm to about 750 nm, but embodiments are not limited to this example.

The second light emitting element LE2 may emit second light different from the first light. The second light may be green light. For example, a peak wavelength (G-peak) of the second light may be in a range of about 480 nm to about 560 nm, but embodiments are not limited to this example.

The third light emitting element LE3 may emit third light, which may be different from both the first light and the second light. The third light may be blue light. For example, a peak wavelength (B-peak) of the third light may be in a range of about 370 nm to about 460 nm, but embodiments are not limited to this example.

In an embodiment, the first light emitting element LE1, the second light emitting element LE2, and the third light emitting element LE3 may emit light of a same color. In some implementations, a light conversion layer including a light conversion element (e.g., quantum dots, quantum rods, and/or the like) for converting the color (or wavelength band corresponding to the color) of light emitted from at least one light emitting element LE into light of another color (or wavelength band corresponding to the other color) may be disposed on (or overlap) the at least one light emitting element LE in, for instance, the third direction DR3 among the first light emitting element LE1, the second light emitting element LE2, and the third light emitting element LE3.

In an embodiment, the first light emitting element LE1, the second light emitting element LE2, and the third light emitting element LE3 of the respective pixels PX may be sequentially disposed in (or arranged along) the first direction DR1. In an embodiment, the first light emitting elements LE1 may be arranged in (or along) the second direction DR2. The second light emitting elements LE2 may be arranged in (or along) the second direction DR2. The third light emitting elements LE3 may be arranged in (or along) the second direction DR2. For example, the first light emitting elements LE1, the second light emitting elements LE2, or the third light emitting elements LE3 may be arranged in (or along) each pixel column extending along the second direction DR2. The arrangement structure of the pixels PX and the light emitting elements LE provided in (or included as part of) the pixels PX may vary according to embodiments.

In an embodiment, the light emitting elements LE may be arranged in the display area DA at substantially equal intervals in the first direction DR1 and the second direction DR2. However, embodiments are not limited to this example. For example, the positions and/or arrangement intervals of the light emitting elements LE may vary according to embodiments.

In an embodiment, sizes (e.g., areas) of the light emitting elements LE may be substantially equivalent. For example, the first light emitting elements LE1, the second light emitting elements LE2, and the third light emitting elements LE3 may have substantially a same size as one another. For instance, the sizes of the light emitting elements LE may refer to planar surface areas of the light emitting elements LE in a view in the third direction DR3 or one or more dimensions (e.g., lengths, widths, etc.) of the light emitting elements LE. However, embodiments are not limited to this example. For instance, the respective sizes of the light emitting elements LE and/or the areas of emission areas corresponding to the light emitting elements LE may vary according to embodiments.

In an embodiment, the respective light emitting elements LE may have a circular planar shape in a view in the third direction DR3, but embodiments are not limited to this example. For example, the respective light emitting elements LE may have a quadrilateral planar shape or other polygonal planar shape, an oval planar shape, an elliptical planar shape, or an irregular shape. The light emitting elements LE may have substantially a same planar shape or may have one or more different planar shapes. In some implementations, planar shapes of different groups of the light emitting elements LE may have a same planar shape or different planar shapes.

The non-display area NDA may include a first panel pad area PDA1 and a second panel pad area PDA3.

The first panel pad area PDA1 may be disposed in (or overlap) the non-display area NDA. The first panel pad area PDA1 may be disposed on a first (e.g., an upper) side of the display panel 100. First panel pads PD1 and second panel pads PD2, which will be described later, may be disposed in the first panel pad area PDA1.

The first panel pad area PDA1 may be electrically connected to a first circuit board CB1 through at least one conductive connection member. For example, the first panel pads PD1 may be electrically connected to circuit pads CPD provided on the first circuit board CB1 through an anisotropic conductive film ACF.

The second panel pad area PDA3 may be disposed in (or overlap) the non-display area NDA. The second panel pad area PDA3 may be disposed on a second (e.g., a lower) side of the backplane substrate 110 or the display panel 100. Third panel pads may be disposed in the second panel pad area PDA3.

The second panel pad area PDA3 and the third panel pads may be substantially equivalent or similar to the first panel pad area PDA1, the first panel pads PD1, and the second panel pads PD2, respectively. However, embodiments are not limited to this example. In some implementations, the second panel pad area PDA3 and the third panel pads may be omitted.

The non-display area NDA may include a common electrode connection part CVA1 surrounding (or circumscribing) the display area DA in a view in the third direction DR3. In some embodiments, the common electrode connection part CVA1 may not completely surround the display area DA.

The common electrode connection part CVA1 may be disposed in the non-display area NDA and may be disposed between the first panel pad area PDA1 and the display area DA, and between the second panel pad area PDA3 and the display area DA. The common electrode connection part CVA1 may be disposed on one (or a first) side and another (or a second) side of the display area DA that oppose one another in (or along) the first direction DR1, and may be disposed on one (or a third) side and another (e.g., a fourth) side of the display area DA that oppose one another in (or along) the second direction DR2. The common electrode connection part CVA1 may include multiple common electrode connectors CVS for providing one or more electrical connections to the backplane substrate 110.

The common electrode connection part CVA1 may surround (or circumscribe) at least a portion of the display area DA in a plan view. For example, as illustrated in FIG. 1, the common electrode connection part CVA1 may completely surround the display area DA. However, embodiments are not limited to this example. For instance, the common electrode connection part CVA1 may be disposed on one (or a) side, two opposing sides, two non-opposing sides, or at least three sides of the display area DA.

The common electrode connection part CVA1 may include multiple common electrode connectors CVS electrically connected to a common electrode (e.g., a common electrode CE in FIG. 2). For example, the common electrode CE may extend from the display area DA to the common electrode connection part CVA1 and may be electrically connected to the common electrode connectors CVS. A common voltage may be supplied to the common electrode CE through the common electrode connectors CVS.

The common electrode connectors CVS may be disposed in a common voltage supply area (e.g., the common electrode connection part CVA1) of the non-display area NDA. The common electrode connectors CVS may include a conductive material (e.g., a metal material, such as aluminum (Al)). Although the display device 10 in which the common electrode connectors CVS are located in the non-display area NDA is shown in FIGS. 1 and 2, embodiments are not limited to this structure or arrangement. For example, the common electrode connectors CVS may be additionally or alternatively located in the display area DA. For example, the common electrode connectors CVS may be located in (or overlap) pixels PX or areas between the pixels PX.

The common electrode connectors CVS of the common electrode connection part CVA1 may be electrically connected to any one of the first panel pads PD1 or the second panel pads PD2 of the first panel pad area PDA1. For example, the common electrode connectors CVS of the common electrode connection part CVA1 may receive a common voltage from any one of the first panel pads PD1 of the first panel pad area PDA1.

The display device 10 may further include the first circuit board CB1 and a second circuit board CB2.

Each of the first circuit board CB1 and the second circuit board CB2 may be a flexible printed circuit board (FPCB), a printed circuit board (PCB), a flexible printed circuit (FPC), or a flexible film, such as chip on film (COF). Embodiments, however, are not limited to these examples.

The first circuit board CB1 and the second circuit board CB2 may overlap edges of the display panel 100, respectively. In a view in the third direction DR3, the display panel 100 may be disposed between the first circuit board CB1 and the second circuit board CB2.

For example, in a plan view, the first circuit board CB1 may face a first side of the display panel 100 that extends in the first direction DR1, and the second circuit board CB2 may face a second side of the display panel 100 that may oppose the first side of the display panel 100 along, for instance, the second direction DR2. As illustrated in FIG. 1, the first circuit board CB1, the display panel 100, and the second circuit board CB2 may be sequentially arranged in (or along) the second direction DR2 in a plan view.

However, embodiments are not limited to the above-noted arrangement. For instance, any one of the first circuit board CB1 and the second circuit board CB2 may face a first side of the display panel 100 that extends in the first direction DR1, and the other one of the first circuit board CB1 and the second circuit board CB2 may face a second side of the display panel 100 that extends in, for instance, the second direction DR2. In some embodiments, the second circuit board CB2 may be omitted.

Referring to FIG. 2, the display panel 100 may include the backplane substrate 110 and a light emitting element layer 120. In an embodiment, the display panel 100 may further include an optical structure (and/or a light output structure), for example, one or more (e.g., multiple) lens-type optical structures LS provided (or disposed) on the light emitting element layer 120.

The display panel 100 may further include one or more additional components depending on an embodiment. For example, the display panel 100 may further include a light conversion layer for converting the color and/or wavelength of light emitted from at least some of the light emitting elements LE and/or a color filter layer for controlling light of a specific (or determined) color to be emitted from each emission area EA.

The display panel 100 may include emission areas EA located (or disposed) in the display area DA. Each of the emission areas EA may include at least one light emitting element LE. For example, the emission areas EA may include first emission areas EA1, each including at least one first light emitting element LE1, second emission areas EA2, each including at least one second light emitting element, and third emission areas EA3, each including at least one third light emitting element LE3. In an embodiment, the first light, the second light, and the third light may be emitted from the first emission areas EA1, the second emission areas EA2, and the third emission areas EA3, respectively.

The backplane substrate 110 may include (or may include a portion in or overlapping) the display area DA, which may include the emission areas EA. In an embodiment, the backplane substrate 110 may be a semiconductor circuit board formed by a semiconductor process using a wafer, such as a silicon wafer. For example, the silicon wafer may be used as a base member for forming the display panel 100.

The backplane substrate 110 may include the pixel circuits PXC and the pixel electrodes PXE disposed on a portion of the backplane substrate 100 and in the display area DA. For example, at least one light emitting element LE may be disposed in each emission area EA of the display panel 100, and the backplane substrate 110 may include the pixel circuits PXC and the pixel electrodes PXE connected (e.g., electrically connected) to the light emitting elements LE respectively disposed in the emission areas EA.

In an embodiment, the backplane substrate 110 may further include a first insulating layer INS1 disposed around (or between) the pixel electrodes PXE. For instance, in a view in the third direction DR3, the first insulating layer INS1 may circumscribe the pixel electrodes PXE or may at least be disposed between adjacent pixel electrodes PXE.

The pixel circuits PXC may be provided in the display area DA to respectively correspond to areas in which the pixels PX and/or the emission areas EA are formed, respectively. In an embodiment, each of the pixel circuits PXC may include a complementary metal-oxide-semiconductor (CMOS) circuit formed using a semiconductor process.

Each of the pixel circuits PXC may include at least one transistor formed through a semiconductor process. In addition, each of the pixel circuits PXC may further include at least one capacitor formed through a semiconductor process.

The pixel circuits PXC may be electrically connected to the pixel electrodes PXE, respectively. For example, the pixel circuits PXC and the pixel electrodes PXE may be electrically connected in one-to-one correspondence with each other. Each of the pixel circuits PXC may apply a pixel voltage to a corresponding pixel electrode PXE electrically connected to that pixel circuit PXC.

The pixel electrodes PXE may be electrically connected to the pixel circuits PXC, respectively. The pixel electrodes PXE may be individually provided in the emission areas EA, respectively, and may be electrically connected to the light emitting elements LE respectively located in the emission areas EA. The light emitting elements LE respectively disposed in the emission areas EA may be controlled individually and/or independently from one another.

Each of the pixel electrodes PXE may be disposed on a corresponding pixel circuit PXC. For instance, each of the pixel electrodes PXE may overlap a portion of a corresponding pixel circuit PXC in the third direction DR3. In an embodiment, each of the pixel electrodes PXE may be an electrode formed integrally with (and/or integral to) the pixel circuit PXC and exposed from the pixel circuit PXC. For example, each of the pixel electrodes PXE may protrude from a surface (e.g., an upper surface) of the pixel circuit PXC. Each of the pixel electrodes PXE may receive a pixel voltage from a corresponding pixel circuit PXC. The pixel electrodes PXE may include a conductive material (e.g., a metal material, such as aluminum (Al), but embodiments are not limited to this example).

In an embodiment, the first insulating layer INS1 may be disposed around the pixel electrodes PXE in a view in, for instance, the third direction DR3. The first insulating layer INS1 may be provided on a surface (e.g., an upper surface) of the semiconductor circuit board in (or on) which the pixel circuits PXC are formed. In an embodiment, the first insulating layer INS1 may be disposed between the pixel electrodes PXE to surround (or circumscribe) the pixel electrodes PXE.

The first insulating layer INS1 may expose at least a portion of each of the pixel electrodes PXE. For example, the first insulating layer INS1 may include openings corresponding to the pixel electrodes PXE and may expose surfaces (e.g., upper surfaces) of the pixel electrodes PXE through the openings. The first insulating layer INS1 may include an inorganic insulating material, such as at least one of silicon oxide (SiOₓ), silicon nitride (SiNₓ), silicon oxynitride (SiOₓN_{y}), aluminum oxide (AlₓO_{y}), and aluminum nitride (AlN), and/or any other suitable insulating material.

The backplane substrate 110 may further include (or may further include a portion in or overlapping) the non-display area NDA, such as illustrated in FIGS. 1 and 2. In an embodiment, the backplane substrate 110 may further include the common electrode connectors CVS, the first panel pads PD1, the second panel pads PD2, etc., disposed on a portion of the backplane substrate 110 and in the non-display area NDA.

In an embodiment, the common electrode connectors CVS may be disposed in (or as portions of) the common electrode connection part CVA1 of the non-display area NDA. For example, the common electrode connectors CVS may be disposed on opposing sides of the display area DA.

In an embodiment, each of the common electrode connectors CVS may include a first common connection electrode CCE1, a second common connection electrode CCE2, and a third common connection electrode CCE3. The first common connection electrode CCE1 may include a same material as the pixel electrodes PXE. In some embodiments, the first common connection electrode CCE1 and the pixel electrodes PXE may be formed through a same process and/or from a same initial layer of material. The first common connection electrode CCE1 and the pixel electrodes PXE may be formed to have a same thickness in the third direction DR3.

The second common connection electrode CCE2 may be disposed on the first common connection electrode CCE1. The second common connection electrode CCE2 may include a same material as bonding electrodes BOE. In some implementations, the second common connection electrode CCE2 and the bonding electrodes BOE may be formed through a same process and/or from a same initial layer of material. However, in some embodiments, the second common connection electrode CCE2 may have a smaller thickness than the bonding electrodes BOE in the third direction DR3.

The third common connection electrode CCE3 may be disposed on the second common connection electrode CCE2 and may transmit a common voltage signal from the second common connection electrode CCE2 to the light emitting elements LE. The third common connection electrode CCE3 may be made of a same material as the bonding electrodes BOE, but embodiments are not limited thereto. The third common connection electrode CCE3 may be relatively thick in the third direction DR3 to electrically connect the second common connection electrode CCE2 and the light emitting elements LE to one another.

The first panel pads PD1 may be electrically connected to the circuit pads CPD of the first circuit board CB1 through the anisotropic conductive film ACF. For instance, the first panel pads PD1 and the circuit pads CPD of the first circuit board CB1 may be electrically connected to each other in one-to-one correspondence.

In an embodiment, each of the first panel pads PD1 may include a first pad electrode PDE1 and a second pad electrode PDE2. The first pad electrode PDE1 may include a same material as the first common connection electrode CCE1. In some implementations, the first pad electrode PDE1 and the first common connection electrode CCE1 may be formed through a same process and/or from a same initial layer of material. The first pad electrode PDE1 and the first common connection electrode CCE1 may be formed having a same thickness in the third direction DR3 as one another.

The second pad electrode PDE2 may be disposed on the first pad electrode PDE1. The second pad electrode PDE2 may include a same material as the second common connection electrode CCE2. In some embodiments, the second pad electrode PDE2 may be formed through a same process as the second common connection electrode CCE2 and the bonding electrodes BOE and/or from a same initial layer of material. The second pad electrode PDE2 may be formed having a same thickness as the second common connection electrode CCE2 in the third direction DR3. However, the second pad electrode PDE2 may have a smaller thickness than the bonding electrodes BOE in the third direction DR3.

Like the first panel pads PD1, the second panel pads PD2 may each include a first pad electrode PDE1 and a second pad electrode PDE2. The second panel pads PD2 may function as pads for test driving (or testing) the display panel 100 or as dummy pads. For descriptive convenience, embodiments in which the second panel pads PD2 are dummy pads will, herein, be described as an example.

According to an embodiment, the first panel pad area PDA1 may further include a planarization layer PLL, a connection electrode CNE, and an upper pad electrode PCE.

The planarization layer PLL may be disposed on the first panel pad area PDA1 and may insulate and planarize a surface overlying the first panel pads PD1 and the second panel pads PD2. The planarization layer PLL may be made of an organic material that can perform a planarization function, but embodiments are not limited to this example.

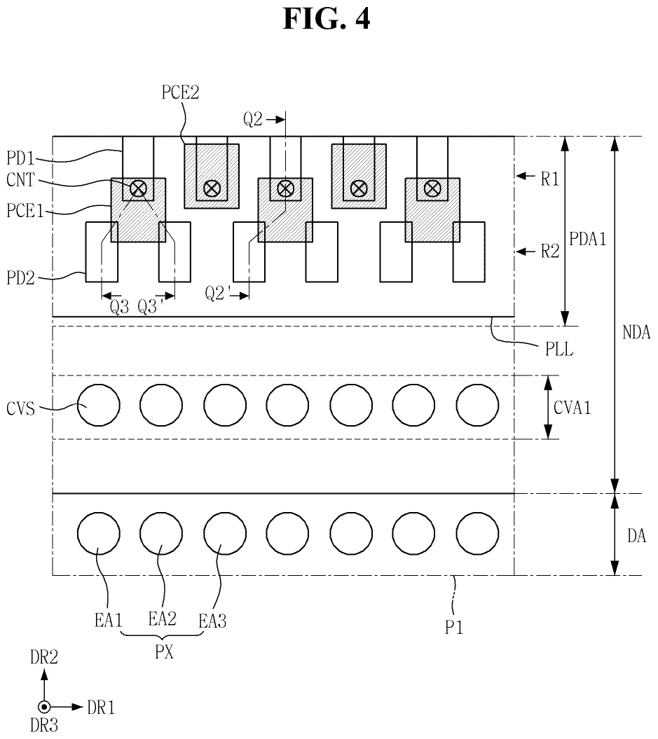

The connection electrode CNE may electrically connect the second pad electrode PDE2 of a first panel pad PD1 to the upper pad electrode PCE. The connection electrode CNE may fill a contact hole CNT (see, e.g., FIG. 4) of the planarization layer PLL as will be described later. The connection electrode CNE may be made of a metal material with relatively low resistance.

The upper pad electrode PCE may be disposed on both the planarization layer PLL and the connection electrode CNE. The upper pad electrode PCE may be electrically connected to the second pad electrode PDE2 of a first panel pad PD1 through the connection electrode CNE. The upper pad electrode PCE may be electrically connected to a circuit pad CPD of the first circuit board CB 1 through the anisotropic conductive film ACF.

The light emitting element layer 120 may include the bonding electrodes BOE, the light emitting elements LE, and the common electrode CE. In an embodiment, the light emitting element layer 120 may further include an organic layer ORL disposed around or at least adjacent to the light emitting elements LE in a view in the third direction DR3 and/or a second insulating layer INS2 disposed on the common electrode CE.

In an embodiment, the light emitting element layer 120 may further include one or more additional components. For example, the light emitting element layer 120 may further include a reflective layer and/or a light blocking layer disposed between the light emitting elements LE and/or on side surfaces (e.g., lateral side surfaces) of the light emitting elements LE.

The bonding electrodes BOE may be disposed at positions respectively corresponding to the pixel electrodes PXE and may be electrically connected to the pixel electrodes PXE, respectively. For example, the bonding electrodes BOE may be disposed on the pixel electrodes PXE, respectively. The bonding electrodes BOE may be individually patterned into shapes corresponding to the shapes of the pixel electrodes PXE, respectively. For example, the bonding electrodes BOE may be patterned to have sizes and/or planar shapes corresponding to the sizes and/or planar shapes of the pixel electrodes PXE, respectively, and thus, may be separated from each other.

Each of the bonding electrodes BOE may include a first bonding electrode and a second bonding electrode. The second bonding electrode may be disposed on the first bonding electrode, and the first bonding electrode and the second bonding electrode may have sizes and planar shapes corresponding to each other.

The first bonding electrode and the second bonding electrode may include a conductive bonding material suitable for bonding or attaching the light emitting elements LE onto the pixel electrodes PXE. For example, each of the second bonding electrodes may be a single-layer or multilayer electrode including at least one of gold (Au), copper (Cu), aluminum (Al), and tin (Sn), and/or any other suitable metal materials (e.g., bonding metals).

The light emitting elements LE may be disposed on the bonding electrodes BOE, respectively. Each of the light emitting elements LE may be electrically connected between a corresponding one of the pixel electrodes PXE and the common electrode CE.

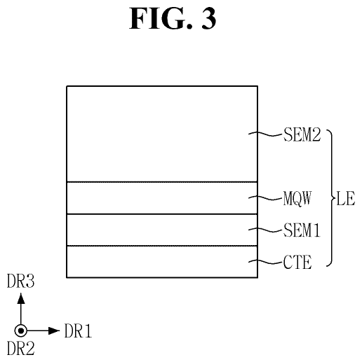

The light emitting elements LE may include semiconductor layers grown on a semiconductor substrate (e.g., a wafer substrate) by epitaxial growth, but any other suitable method of forming the semiconductor layers may be utilized. For example, each of the light emitting elements LE may include a first semiconductor layer doped with a first conductivity type, a second semiconductor layer doped with a second conductivity type, and an active layer interposed between the first semiconductor layer and the second semiconductor layer. An example structure of a light emitting element LE will be described in more detail in association with FIG. 3.

The light emitting elements LE may be formed from one or more epitaxial thin films grown on a semiconductor wafer, which may be split or diced into multiple dies corresponding to the light emitting elements LE. The light emitting elements LE may be patterned or disposed in a cell area of a display panel 100 and may be formed in the emission areas EA, respectively. Some example structures and manufacturing methods of the light emitting elements LE according to some embodiments will be described in more detail later.

In a view in the third direction DR3, the organic layer ORL may be provided around (or adjacent to) the respective light emitting elements LE. For example, in a view in the third direction DR3, the organic layer ORL may be disposed between the emission areas EA to surround (or circumscribe) the emission areas EA in which the light emitting elements LE are provided and may surround (or circumscribe) the light emitting elements LE and the second bonding electrodes. In an embodiment, the organic layer ORL may be a filler that fills one or more gaps between the light emitting elements LE. The organic layer ORL may expose a portion, e.g., an upper surface of each light emitting element LE.

The organic layer ORL may include an insulating material. For example, the organic layer ORL may be a single-layer or a multilayer organic insulating layer including, for instance, at least one of acryl resin, epoxy resin, phenolic resin, polyamide resin, and polyimide resin, and/or any other suitable organic insulating material.

The common electrode CE may be disposed on portions of the light emitting elements LE not covered by the organic layer ORL, e.g., the common electrode CE may be disposed on the upper surfaces of the light emitting elements LE exposed by openings in the organic layer ORL. In an embodiment, the common electrode CE may be entirely (or substantially entirely) disposed in the display area DA to cover (or overlap) the light emitting elements LE and the organic layer ORL in, for instance, the third direction DR3. The common electrode CE may be a common layer commonly formed and/or electrically connected to the light emitting elements LE of the display area DA and the pixels PX including the light emitting elements LE. In some implementations, multiple common electrodes CE may be utilized and may be formed in association with one or more light emitting elements LE. In a case that multiple common electrodes CE are utilized, the multiple common electrodes CE may be electrically connected to one another and/or may be electrically connected to a same voltage source to receive a common voltage. Hereinafter, it will be assumed that the common electrode CE is formed in common with the light emitting elements LE of the display area DA of the display panel 100.

The common electrode CE may be electrically connected to the common electrode connectors CVS disposed in the common electrode connection part CVA1 depicted in, for instance, FIGS. 1 and 2. The common electrode CE may receive a common voltage through the common electrode connectors CVS.

The common electrode CE may include a transparent conductive material that can transmit light. For example, the common electrode CE may be made of at least one of indium tin oxide (ITO), and indium zinc oxide (IZO), and/or any other suitable transparent conductive materials, such as a transparent conductive polymer, which may be a derivative of, for instance, at least one of polyacetylene, polyaniline, polypyrrole, and polythiophenes. In an embodiment, the common electrode CE may function as a cathode (or anode) of each light emitting element LE.

The second insulating layer INS2 may be disposed on the common electrode CE. For example, the second insulating layer INS2 may be a capping layer disposed in the entire (or substantially entire) display area DA to cover (or overlap) the common electrode CE in, for instance, the third direction DR3. The second insulating layer INS2 may include an inorganic insulating material, such as at least one of silicon oxide (SiOₓ), silicon nitride (SiNₓ), silicon oxynitride (SiOₓN_{y}), aluminum oxide (AlₓO_{y}), and aluminum nitride (AlN), and/or any other suitable insulating material.

In an embodiment, the display panel 100 may include lens-type optical structures LS disposed on the light emitting element layer 120. The display panel 100 may further include a protective layer PRL covering (or overlapping) the lens-type optical structures LS in, for instance, the third direction DR3.

The lens-type optical structures LS may be disposed in the emission areas EA to overlap the light emitting elements LE, respectively. In an embodiment, the lens-type optical structures LS may be convex lens-shaped optical structures LS provided on the light emitting elements LE. The convexity of the lens-shaped optical structures LS may be defined relative to a surface of the light emitting element layer 120 on which the lens-shaped optical structures LS may be disposed. However, the type and/or shape of the optical structures are not limited to the above-noted examples. The lens-type optical structures LS disposed on the light emitting elements LE can adjust and/or improve the light output characteristics of the pixels PX.

The lens-type optical structures LS may be made of a transparent material to allow light incident from the light emitting elements LE to be transmitted therethrough. For example, the lens-type optical structures LS may be made of at least one of glass, plastic, and ceramic, and/or any other suitable material and may be made of an optical material having a relatively high refractive index.

The protective layer PRL may be disposed on the lens-type optical structures LS to cover (or overlap) the lens-type optical structures LS. The protective layer PRL may be made of a transparent and durable material (e.g., at least one of plastic or organic glass, optical glass, and ceramic, and/or any other suitable material). The material of the protective layer PRL is not limited as long as the material is suitable for protecting the lens-type optical structures LS and relatively transparent to allow light to propagate through the protective layer PRL. Although FIG. 2 depicts an embodiment in which a surface (e.g., an upper surface) of the protective layer PRL has multiple curves corresponding to the shapes of the lens-type optical structures LS, embodiments are not limited to this example structure. For example, the protective layer PRL may be formed having a shape that planarizes an upper surface of the display panel 100 overlapping the lens-type optical structures LS.

FIG. 3 is a schematic cross-sectional view of a light emitting element LE according to an embodiment.

Referring to FIG. 3, the light emitting element LE may include a first semiconductor layer SEM1, an active layer MQW, and a second semiconductor layer SEM2 sequentially disposed and/or stacked on one another along the third direction DR3. In an embodiment, the light emitting element LE may further include a contact electrode CTE disposed at one (or an) end of the light emitting element LE. For example, the light emitting element LE may further include the contact electrode CTE disposed at an end where the first semiconductor layer SEM1 is located. For instance, the first semiconductor layer SEM1 may be disposed on the contact electrode CTE such that the first semiconductor layer SEM1 is interposed between the active layer MQW and the contact electrode CTE.

The light emitting element LE may further include one or more additional layers depending on embodiments. For example, the light emitting element LE may include an electron blocking layer disposed between the first semiconductor layer SEM1 and the active layer MQW and/or a superlattice disposed between the active layer MQW and the second semiconductor layer SEM2.

In an embodiment, the light emitting element LE may be an inorganic light emitting element made of an inorganic material. For example, the light emitting element LE may be an inorganic light emitting diode made of at least one nitride-based semiconductor material, such as at least one of GaN, AlGaN, InGaN, AlInGaN, AlN, and InN, and at least one phosphide-based semiconductor material, such as at least one of GaP, GaInP, AlGaP, AlGaInP, AlP, and InP, and/or any other suitable inorganic material.

The contact electrode CTE may be disposed and/or formed at one (or an) end of the light emitting element LE where the first semiconductor layer SEM1 is disposed. For example, the contact electrode CTE may be disposed and/or formed on a surface of the first semiconductor layer SEM1. The contact electrode CTE may be an electrode for protecting the first semiconductor layer SEM1 and electrically connecting the first semiconductor layer SEM1 to at least one circuit element, electrode, line, and/or conductive layer. The contact electrode CTE may include at least one of a metal and a metal oxide, and/or any other suitable conductive material.

The first semiconductor layer SEM1 may be disposed on the contact electrode CTE. In an embodiment, the first semiconductor layer SEM1 may include a nitride-based semiconductor material or a phosphide-based semiconductor material. For example, the first semiconductor layer SEM1 may include a nitride-based semiconductor material including at least one of GaN, AlGaN, InGaN, AlInGaN, AlN and InN, or a phosphide-based semiconductor material including at least one of GaP, GaInP, AlGaP, AlGaInP, AlP and InP. The first semiconductor layer SEM1 may additionally or alternatively include other materials.

The first semiconductor layer SEM1 may include a semiconductor material doped with a first conductivity type dopant. For example, the first semiconductor layer SEM1 may be made of GaN (e.g., p-GaN) doped with a first conductivity type dopant (e.g., a p-type dopant), such as Mg, Zn, Ca, Se, and/or Ba.

The active layer MQW may be disposed on the first semiconductor layer SEM1. The active layer MQW may emit light through recombination of electron-hole pairs according to electrical signals received through the first semiconductor layer SEM1 and the second semiconductor layer SEM2. For example, the active layer MQW may be a light emitting layer of the light emitting element LE.

The active layer MQW may include a material having a single or a multiple quantum well structure. In a case that the active layer MQW includes a material having a multiple quantum well structure, the active layer MQW may have a structure in which multiple well layers and multiple barrier layers are alternately stacked on each other, The active layer MQW may include different group 3 to 5 semiconductor materials depending on a wavelength band of light that the active layer MQW may be configured to emit.

In an embodiment, the active layer MQW may include a nitride-based semiconductor material or a phosphide-based semiconductor material. For example, the active layer MQW may include a nitride-based semiconductor material including at least one of GaN, AlGaN, InGaN, InGaAlN, AlN, InN, and AlInN, or a phosphide-based semiconductor material including at least one of GaP, GaInP, AlGaP, AlGaInP, AlP, and InP. For example, a well layer may be made of InGaN, and a barrier layer may be made of GaN or AlGaN, but embodiments are not limited to this example. In a case that the active layer MQW includes InGaN, the color of light emitted from the light emitting element LE may be controlled by adjusting a content of indium (In) in the active layer MQW. The active layer MQW may additionally or alternatively include other materials.

In an embodiment, the active layers MQW of the first light emitting elements LE1, the second light emitting elements LE2, and the third light emitting elements LE3 illustrated in FIG. 2 may emit light of a same color (e.g., blue light). In an embodiment, the active layers MQW of the first light emitting elements LE1, the second light emitting elements LE2, and the third light emitting elements LE3 may emit light of different colors from one another (e.g., red light, green light, and blue light respectively).

The second semiconductor layer SEM2 may be disposed on the active layer MQW. In an embodiment, the second semiconductor layer SEM2 may include a nitride-based semiconductor material or a phosphide-based semiconductor material. For example, the second semiconductor layer SEM2 may include a nitride-based semiconductor material including at least one of GaN, AlGaN, InGaN, AlInGaN, AlN, and InN, or a phosphide-based semiconductor material including at least one of GaP, GaInP, AlGaP, AlGaInP, AlP, and InP. The second semiconductor layer SEM2 may additionally or alternatively include other materials.

The second semiconductor layer SEM2 may include a semiconductor material doped with a second conductivity type dopant. For example, the second semiconductor layer SEM2 may be made of GaN (e.g., n-GaN) doped with a second conductivity type dopant (e.g., an n-type dopant), such as Si, Ge, and/or Sn.

In an embodiment, the first semiconductor layer SEM1 and the second semiconductor layer SEM2 may have different thicknesses from one another in a thickness direction (e.g., the third direction DR3) of the light emitting element LE. For example, the second semiconductor layer SEM2 may have a greater thickness than the first semiconductor layer SEM1 in a thickness direction of the light emitting element LE. The active layer MQW may be located closer to a first end (e.g., a p-type end) of the light emitting element LE where the first semiconductor layer SEM1 is provided (or disposed) than to a second end (e.g., an n-type end) of the light emitting element LE where the second semiconductor layer SEM2 is provided (or disposed).

In an embodiment, the light emitting element LE may be a vertical micro-LED extending and/or stacked in the third direction DR3. For example, the light emitting element LE may be a micro-LED having a length in the first direction DR1, a length in the second direction DR2, and a length in the third direction DR3 that are each in a range of about several micrometers (μm) to about hundreds of μm. In an embodiment, a length of the light emitting element LE in the first direction DR1, a length of the light emitting element LE in the second direction DR2, and a length of the light emitting element LE in the third direction DR3 may each be in a range of greater than 0 μm to about 100 μm.

In an embodiment, the light emitting element LE may include substantially vertical side surfaces (e.g., lateral side surfaces) as illustrated in FIG. 3. For example, the light emitting element LE may be patterned through vertical etching and may have a rectangular or square cross-sectional shape in a plane parallel (or substantially parallel) to a DR1-DR3 plane such that upper and lower surfaces of the light emitting element LE have substantially a same width in a plane parallel (or substantially parallel) to a DR1-DR2 plane.

The shape of the light emitting element LE may vary according to embodiments. For example, the light emitting element LE may have a cross-sectional shape in a plane parallel (or substantially parallel) to a DR1-DR3 plane such that upper and lower surfaces of the light emitting element LE have different widths in a plane parallel (or substantially parallel) to a DR1-DR2 plane. However, embodiments are not limited to this example. For example, the light emitting element LE may have a reverse-tapered cross-sectional shape in a plane parallel (or substantially parallel) to a DR1-DR3 plane. For instance, the light emitting element LE may have an inverted trapezoidal cross-sectional shape in a plane parallel (or substantially parallel) to a DR1-DR3 plane such that an upper surface of the light emitting element LE is wider in a plane parallel (or substantially parallel) to a DR1-DR2 plane than a lower surface of the light emitting element LE.

In an embodiment, the light emitting element LE may be disposed on the backplane substrate 110 such that the first semiconductor layer SEM1 is located below the active layer MQW (e.g., closer to the backplane substrate 110), and the second semiconductor layer SEM2 is located above the active layer MQW (e.g., further from the backplane substrate 110) as illustrated in FIG. 3. For example, the light emitting element LE may be disposed in each emission area EA such that the contact electrode CTE (or the first semiconductor layer SEM1) contacts a bonding electrode BOE (such as shown in FIG. 2), and the second semiconductor layer SEM2 (or another contact electrode disposed on the second semiconductor layer SEM2) contacts the common electrode CE, which may be a cathode of the light emitting element LE.

The structure, material, size, and/or shape of the light emitting element LE are not limited to the above-described embodiments. For example, the structure, material, size, and/or shape of the light emitting element LE may vary according to embodiments.

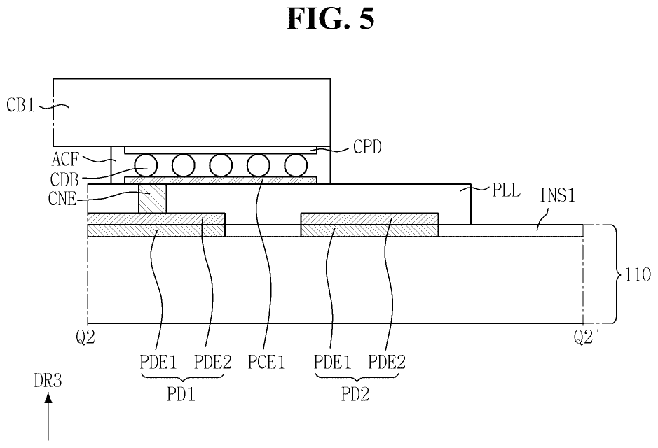

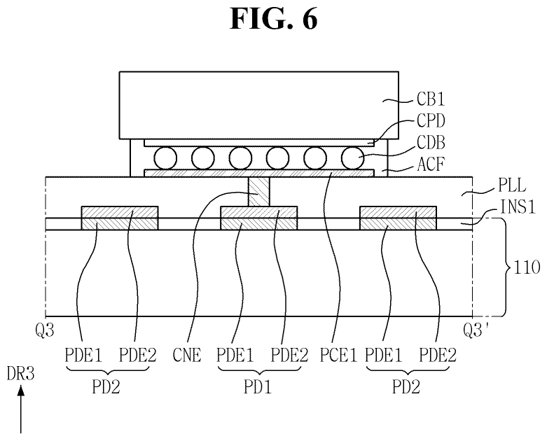

FIG. 4 is an enlarged, schematic plan view of part P1 of FIG. 1 according to an embodiment. FIG. 5 is a schematic cross-sectional view taken along sectional line Q2-Q2′ of FIG. 4 according to an embodiment. FIG. 6 is a schematic cross-sectional view taken along sectional line Q3-Q3′ of FIG. 4 according to an embodiment.

Referring to FIGS. 4 through 6, the first panel pad area PDA1 may include multiple first panel pads PD1 and multiple second panel pads PD2.

The first panel pads PD1 and the second panel pads PD2 may be disposed in the first panel pad area PDA1. The first panel pads PD1 may be disposed on the backplane substrate 110.

The first panel pads PD1 may extend in the second direction DR2 in a plan view and may be disposed to form a row in which the first panel pads PD1 are spaced apart from each other in the first direction DR1. The second panel pads PD2 may extend in the second direction DR2 in a plan view and may be disposed to form a row in which the second panel pads PD2 are spaced apart from each other in the first direction DR1. The first panel pads PD1 and the second panel pads PD2 may be spaced apart from each other in at least the second direction DR2. For example, as illustrated in FIG. 4, an arrangement of the first panel pads PD1 may form a first row R1 extending in the first direction DR1, and an arrangement of the second panel pads PD2 may form a second row R2 extending in the first direction DR1. However, embodiments are not limited to this example. For instance, the first panel pads PD1 and the second panel pads PD2 may be disposed or arranged to respectively form two or more rows.

The first panel pads PD1 may be disposed closer to an edge of the backplane substrate 110 or an edge of the first panel pad area PDA1 than the second panel pads PD2. The second panel pads PD2 may be disposed closer to the display area DA or the common electrode connection part CVA1 of the display panel 100 than the first panel pads PD1.

The first panel pads PD1 and the second panel pads PD2 may be disposed or arranged to form a zigzag pattern in a plan view. For instance, as illustrated in FIG. 4, the first panel pads PD1 in the first row R1 may be arranged with a first pitch in the first direction DR1, and the second panel pads PD2 in the second row R2 may be arranged with a second pitch in the first direction DR1. The first pitch and the second pitch may be equivalent, but embodiments are not limited to this example. The first panel pads PD1 may be offset from the second panel pads PD2 in the second direction DR2 in a plan view. Spaces between the first panel pads PD1 of the first row R1 may not overlap the second panel pads PD2 of the second row R2 in the third direction DR3 in a plan view. The first pitch and the second pitch may be substantially equivalent to a pitch at which a plurality of emission areas (e.g., first through third emission areas EA1 through EA3) are arranged. However, embodiments are not limited to this example.

The first panel pads PD1 in the first row R1 and the second panel pads PD2 in the second row R2 may be arranged at a third pitch in the second direction DR2. For example, the first panel pads PD1 and the second panel pads PD2 may be spaced apart from one another by the third pitch in the second direction DR2.

The first panel pads PD1 in the first row R1 may be located in a diagonal direction, which may be transverse to both the first direction DR1 and the second direction DR2 in a plan view, with respect to the second panel pads PD2 in the second row R2 closest to the first row R1.

The first panel pads PD1 and the second panel pads PD2 may have a rectangular planar shape in a plan view. A total number of the first panel pads PD1 and a total number of the second panel pads PD2 may be equivalent, but embodiments are not limited to this example. In addition, any suitable number of the first panel pads PD1 and the second panel pads PD2 may be utilized provided that sufficient space is available for the first panel pads PD1 and the second panel pads PD2. However, embodiments are not limited to these examples. For instance, the first panel pads PD1 and the second panel pads PD2 may have any suitable geometric planar shape, such as a circular planar shape, a square planar shape, an oval planar shape, an elliptical planner shape, a diamond planar shape, a freeform (or irregular) planar shape, etc.

The planarization layer PLL may be disposed on the first panel pads PD1 and the second panel pads PD2 in the first panel pad area PDA1. The planarization layer PLL may cover (or overlap) the first panel pads PD1 and the second panel pads PD2 and may be aligned with sides (e.g., lateral sides) of the backplane substrate 110. The planarization layer PLL may insulate the first panel pads PD1 and the second panel pads PD2 from each other and may flatten steps that might otherwise be formed in a surface overlying the first panel pads PD1 and the second panel pads PD2. The planarization layer PLL may be disposed in a portion of the first panel pad area PDA1. For example, the planar surface area of the planarization layer PLL may be smaller than the planar surface area of the first panel pad area PDA1 in a view in the third direction.

The planarization layer PLL may include a plurality of contact holes CNT. The contact holes CNT may overlap the first panel pads PD1 and expose surfaces (e.g., upper surfaces) of the first panel pads PD1. The contact holes CNT may be disposed in correspondence with the first panel pads PD1. For example, the contact holes CNT may correspond one-to-one with the first panel pads PD1. One (or a) contact hole CNT may be disposed on one (or a) side of a first panel pad PD1. For example, the contact hole CNT may be disposed on the first panel pad PD1 and may be adjacent to one or more second panel pads PD2, such as two second panel pads PD2.

A plurality of connection electrodes CNE may be disposed on the first panel pad area PDA1. The connection electrodes CNE may respectively overlap and correspond to the first panel pads PD1. For example, the connection electrodes CNE may correspond one-to-one with the first panel pads PD1 and respectively overlap the first panel pads in the third direction DR3.

The connection electrodes CNE may be disposed in the contact holes CNT in the planarization layer PLL. The connection electrodes CNE may fill the contact holes CNT, respectively. The connection electrodes CNE may not protrude from (e.g., above) the planarization layer PLL and may be disposed such that a surface (e.g., an upper surface) of the planarization layer PLL is level with corresponding surfaces (e.g., corresponding upper surfaces) of the connection electrodes CNE. The surfaces of the connection electrodes CNE may be formed co-planar with the corresponding surface of the planarization layer PLL through a polishing process, such as a chemical mechanical polishing (CMP) process performed after the formation of the connection electrodes CNE in the contact holes CNT. The connection electrodes CNE may be made of a metal that has relatively low contact resistance with the first panel pads PD1. For example, the connection electrodes CNE may include at least one of gold (Au), copper (Cu), aluminum (Al), and tin (Sn), but embodiments are not limited to these materials.

Multiple upper pad electrodes (e.g., first upper pad electrodes PCE1 and second upper pad electrodes PCE2) may be disposed on the planarization layer PLL. Hereinafter, the first upper pad electrodes PCE1 and the second upper pad electrodes PCE2 may be collectively referred to as “the upper pad electrodes PCE1 and PCE2.” The upper pad electrodes PCE1 and PCE2 may include multiple first upper pad electrodes PCE1 and multiple second upper pad electrodes PCE2.

The first upper pad electrodes PCE1 and the second upper pad electrodes PCE2 may be disposed to form a zigzag pattern in a plan view. The first upper pad electrodes PCE1 and the second upper pad electrodes PCE2 may be disposed alternately with each other in (or along) the first direction DR1. The first upper pad electrodes PCE1 and the second upper pad electrodes PCE2 may be disposed alternately with each other to overlap the first panel pads PD1 in the third direction DR3. For example, a first instance of the first upper pad electrodes PCE1 may overlap a side of a first instance of the first panel pads PD1, and a second upper pad electrode PCE2 may overlap a second instance of the first panel pads PD1 that is adjacent to the first instance of the first panel pads PD1.

Each of the first upper pad electrodes PCE1 may overlap one or more of the second panel pads PD2 in the third direction DR3 in addition to overlapping a corresponding one of the first panel pads PD1 in the third direction DR3. For example, the first instance of the first upper pad electrodes PCE1 may overlap the first instance of the first panel pads PD1 in the third direction DR3 and may also overlap two second panel pads PD2 in the third direction DR3 that are adjacent to the first instance of the first panel pads PD1 in diagonal directions traverse to both the first direction DR1 and the second direction DR2.

The second upper pad electrodes PCE2 may overlap the first panel pads PD1 in the third direction DR3 and may not overlap the second panel pads PD2 in the third direction DR3. For example, the first instance of the second upper pad electrodes PCE2 may overlap the second instance of the first panel pads PD1, and in a view in the third direction DR3, may be spaced apart from two second panel pads PD2 that are adjacent to the second instance of the first panel pads PD1 in diagonal directions traverse to both the first direction DR1 and the second direction DR2.

The first upper pad electrodes PCE1 may be disposed closer to the common electrode connection part CVA1 or the display area DA than the second upper pad electrodes PCE2. The second upper pad electrodes PCE2 may be disposed closer to an edge of the backplane substrate 110 than the first upper pad electrodes PCE1.

The first upper pad electrodes PCE1 may be spaced apart from one another by a first pitch in the first direction DR1, and the second upper pad electrodes PCE2 may be spaced apart from one another by a second pitch in the first direction DR1. The first pitch may be equivalent (or substantially equivalent) to the second pitch, but embodiments are not limited to this example.

The first upper pad electrodes PCE1 and the second upper pad electrodes PCE2 may be disposed on the planarization layer PLL to overlap the connection electrodes CNE in the third direction DR3, respectively. The first upper pad electrodes PCE1 and the second upper pad electrodes PCE2 may contact (e.g., directly contact) surfaces (e.g., upper surfaces) of the connection electrodes CNE. The first upper pad electrodes PCE1 and the second upper pad electrodes PCE2 may be electrically connected to the first panel pads PD1 through the connection electrodes CNE.

A width of each of the first upper pad electrodes PCE1 and the second upper pad electrodes PCE2 may be greater than respective widths of the first panel pads PD1 and/or respective widths of the second panel pads PD2. In a case that the first upper pad electrodes PCE1 and the second upper pad electrodes PCE2 are wider than the first panel pads PD1 (which may be arranged with a relatively fine pitch), the areas of contact of the first upper pad electrodes PCE1 and the second upper pad electrodes PCE2 with conductive balls CDB of the anisotropic conductive film ACF may increase, which may, in turn, improve adhesion reliability.

The display device 10 may include the anisotropic conductive film ACF, which may electrically connect the first panel pads PD1 and the circuit pads CPD of the first circuit board CB1.

The anisotropic conductive film ACF may be disposed on the first panel pad area PDA1. For example, the anisotropic conductive film ACF may be disposed on the planarization layer PLL. The anisotropic conductive film ACF may overlap the first panel pads PD1 and the second panel pads PD2 in the third direction DR3.

The anisotropic conductive film ACF may include an adhesive layer and may also include multiple conductive balls CDB dispersed in the adhesive layer.

The adhesive layer may include resin and may be melted or hardened through application of exogenous heat or may be hardened in a natural state (or without application of exogenous heat). Each of the conductive balls CDB may include an elastic core and a conductive layer covering (or surrounding) the core. The core may include an elastic polymer material, for example, a styrene-based polymer, such as acrylonitrile butadiene styrene (ABS), polystyrene (PS), styrene-acrylonitrile (SAN), or acrylonitrile-styrene-acrylate (ASA), or an acrylic-based polymer, such as poly(methacrylate) (PMA), poly(methyl methacrylate) (PMMA), poly(ethyl methacrylate) (PEMA), or poly(2-hydroxyethyl methacrylate) (poly-HEMA).

As part of manufacturing the display device 10, the anisotropic conductive film ACF may be applied on the first panel pad area PDA1, the first circuit board CB1 may be aligned with respect to the first upper pad electrodes PCE1 and the second upper pad electrodes PCE2, and the first circuit board CB1 may be bonded onto (or with) the first panel pad area PDA1 through, for instance, a compression process using heat. The circuit pads CPD of the first circuit board CB1 may be electrically connected to the first upper pad electrodes PCE1 through the conductive balls CDB.

As described above, in the display device 10 according to some embodiments, the first panel pads PD1 and the second panel pads PD2 may be insulated by the planarization layer PLL on the first panel pad area PDA1, and the upper pad electrodes PCE1 and PCE2 (which may be wider than the first panel pads PD1) may be disposed on the planarization layer PLL. In some implementations, the area of contact between the anisotropic conductive film ACF and the upper pad electrodes PCE1 and PCE2 may increase, thereby improving adhesion reliability.

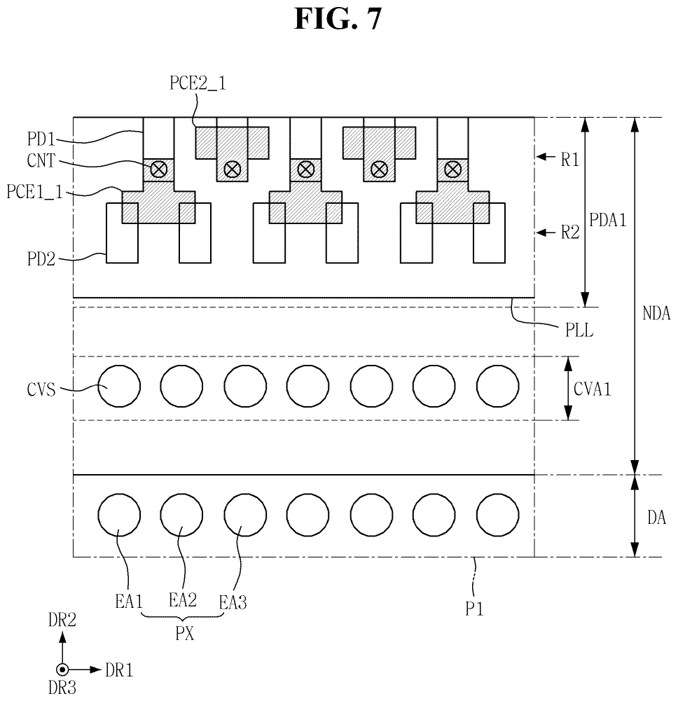

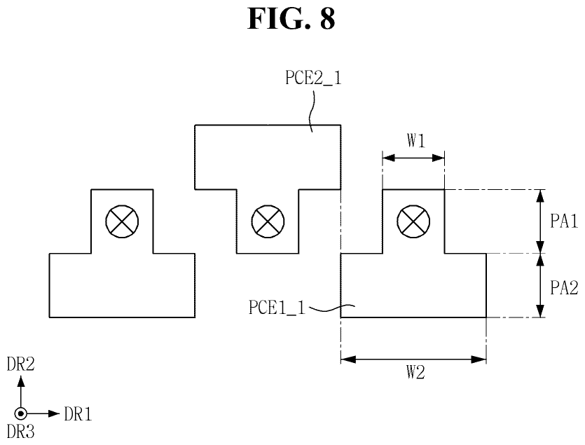

FIG. 7 is an enlarged, schematic plan view of an example of part P1 of FIG. 1 according to an embodiment. FIG. 8 is a schematic plan view illustrating first upper pad electrodes PCE1 and a second upper pad electrode PCE2 of FIG. 7 according to an embodiment.

Referring to FIGS. 7 and 8, first upper pad electrodes PCE1_1 and second upper pad electrodes PCE2_1 have different planar shapes from the planar shapes of the first upper pad electrodes PCE1 and the second upper pad electrodes PCE2 described in association with FIGS. 4 through 6. Other than differences in the planar shapes of the first upper pad electrodes PCE1_1 and second upper pad electrodes PCE2_1, the first upper pad electrodes PCE1_1 and second upper pad electrodes PCE2_1 may be similar to the first upper pad electrodes PCE1 and the second upper pad electrodes PCE2. Therefore, duplicative descriptions will be omitted, and differences will be described below.

Each of the upper pad electrodes PCE1_1 and PCE2_1 may include parts having different widths. For example, each of the first upper pad electrodes PCE1_1 and the second upper pad electrodes PCE2_1 may include parts having different widths. The first upper pad electrodes PCE1_1 and the second upper pad electrodes PCE2_1 may have a same shape apart from differences in orientation. As such, the first upper pad electrodes PCE1_1 will be described as a representative example.

Each of the first upper pad electrodes PCE1_1 may include a first part PA1 and a second part PA2. The first part PA1 may be an area having a smaller width than the second part PA2 in, for instance, the first direction DR1. The first part PA1 may be an area overlapping a first panel pad PD1 in the third direction DR3. The first part PA1 may be formed having a quadrilateral planar shape in a view in the third direction DR3 and may have a first width W1 extending in the first direction DR1. The second part PA2 may be an area extending from the first part PA1. The second part PA2 may be formed having a quadrilateral planar shape in a view in the third direction DR3 and may have a second width W2 extending in the first direction DR1. The first width W1 of the first part PA1 may be smaller than the second width W2 of the second part PA2.

The first part PA1 of each of the first upper pad electrodes PCE1_1 may overlap a first panel pad PD1 and a contact hole CNT in the third direction DR3. The second part PA2 of each of the first upper pad electrodes PCE1_1 may not overlap the first panel pad PD1 in the third direction DR3 and may overlap one or more (e.g., two) second panel pads PD2 in the third direction DR3 that are adjacent to the first panel pad PD1 in diagonal directions traverse to both the first direction DR1 and the second direction DR2.

A first part PA1 of each of the second upper pad electrodes PCE2_1 may overlap a first panel pad PD1 and a contact hole CNT in the third direction DR3. A second part PA2 of each of the second upper pad electrodes PCE2_1 may include a portion overlapping the first panel pad PD1 in the third direction DR3 and one or more other portions that may not overlap the first panel pad PD1 in the third direction DR3 nor second panel pads PD2 in the third direction DR3 that are adjacent to the first panel pad PD1 in diagonal directions traverse to both the first direction DR1 and the second direction DR2. The second part PA2 of each of the second upper pad electrodes PCE2_1 may not overlap the contact hole CNT.

The first parts PA1 of the first upper pad electrodes PCE1_1 and the first parts PA1 of the second upper pad electrodes PCE2_1 may overlap an imaginary line extending in the first direction DR1 in a plan view. The second parts PA2 of the first upper pad electrodes PCE1_1 and the second parts PA2 of the second upper pad electrodes PCE2_1 may not overlap the imaginary line extending in the first direction DR1 in a plan view.

The first upper pad electrodes PCE1_1 and the second upper pad electrodes PCE2_1 may be arranged in a zigzag pattern in a plan view. A direction in which the first part PA1 of each first upper pad electrode PCE1_1 protrudes from the second part PA2 of a corresponding first upper pad electrode PCE1_1 may be opposite a direction in which the first part PA1 of each second upper pad electrode PCE2_1 protrudes from the second part PA2 of a corresponding second upper pad electrode PCE2_1. For example, the direction in which the first part PA1 of each first upper pad electrode PCE1_1 protrudes from the second part PA2 of a corresponding first upper pad electrode PCE1_1 may be a direction opposite the second direction DR2, and the direction in which the first part PA1 of each second upper pad electrode PCE2_1 protrudes from the second part PA2 of a corresponding second upper pad electrode PCE2_1 may be the second direction DR2. The direction in which the first part PA1 of each first upper pad electrode PCE1_1 protrudes from the second part PA2 of a corresponding first upper pad electrode PCE1_1 may be a direction toward the display area DA, and the direction in which the first part PA1 of each second upper pad electrode PCE2_1 protrudes from the second part PA2 of a corresponding second upper pad electrode PCE2_1 may be a direction toward an adjacent side (or edge) of the backplane substrate 110.

In a case that the direction in which the first part PA1 of each first upper pad electrode PCE1_1 protrudes from the second part PA2 of a corresponding first upper pad electrode PCE1_1 is opposite the direction in which the first part PA1 of each second upper pad electrode PCE2_1 protrudes from the second part PA2 of a corresponding second upper pad electrode PCE2_1, the first upper pad electrodes PCE1_1 and the second upper pad electrodes PCE2_1 may have an increased surface area without contacting each other. In some implementations, the area of adhesion between the anisotropic conductive film ACF and the upper pad electrodes PCE1_1 and PCE2_1 may increase, thereby improving adhesion reliability.

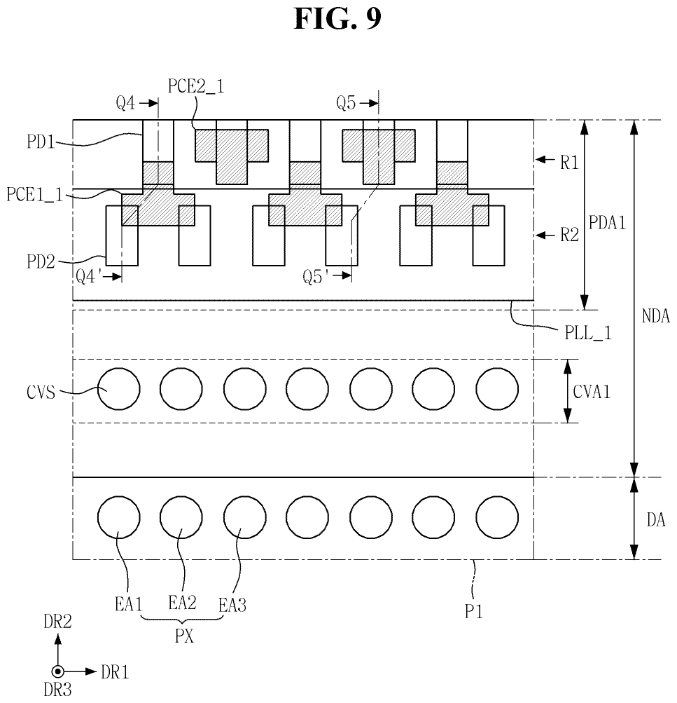

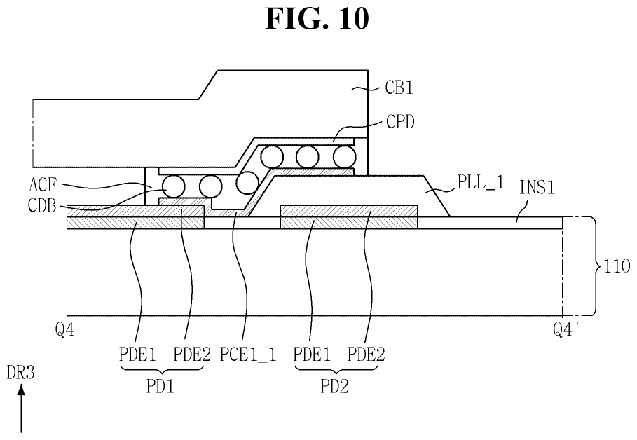

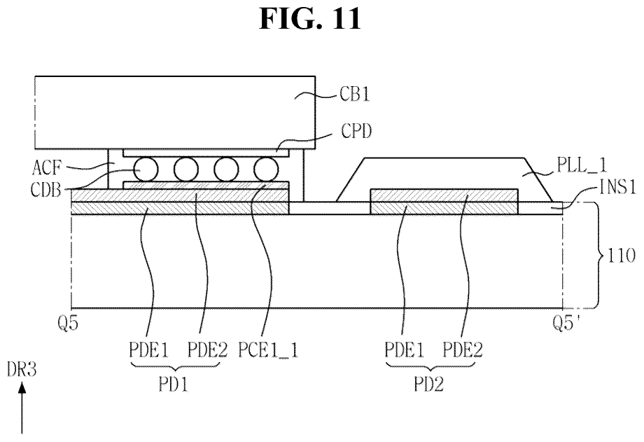

FIG. 9 is an enlarged, schematic plan view of an example of part P1 of FIG. 1 according to an embodiment. FIG. 10 is a schematic cross-sectional view taken along sectional line Q4-Q4′ of FIG. 9 according to an embodiment. FIG. 11 is a schematic cross-sectional view taken along sectional line Q5-Q5′ of FIG. 9 according to an embodiment.

Referring to FIGS. 9 through 11, a planarization layer PLL_1 is different from the planarization layer PLL described in association with FIGS. 4 through 8. As seen in FIGS. 9 through 11, the planarization layer PLL_1 overlaps the second panel pads PD2 in the third direction DR3 and does not overlap first panel pads PD1 in the third direction DR3. Duplicative descriptions will be omitted, and differences will be described below.

The planarization layer PLL_1 may be disposed on a first panel pad area PDA1. The planarization layer PLL_1 may be disposed on the second panel pads PD2. For example, the planarization layer PLL_1 may cover the second panel pads PD2. The planarization layer PLL_1 may be spaced apart from the first panel pads PD1 in a view in the third direction DR3. For example, the planarization layer PLL_1 may not overlap the first panel pads PD1 in the third direction DR3 and may not cover the first panel pads PD1.

At least because the planarization layer PLL_1 does not cover the first panel pads PD1, contact holes CNT in the planarization layer PLL_1 may be omitted.

For example, the first upper pad electrodes PCE1_1 and the second upper pad electrodes PCE2_1 may be disposed on the first panel pads PD1 and the planarization layer PLL_1. The first upper pad electrodes PCE1_1 and the second upper pad electrodes PCE2_1 may be disposed on the first panel pads PD1 to contact (e.g., directly contact) the first panel pads PD1.

The first upper pad electrodes PCE1_1 may extend from the first panel pads PD1 onto the planarization layer PLL_1. In some implementations, the first upper pad electrodes PCE1_1 may be disposed on (e.g., directly on) the first panel pads PD1, the first insulating layer INS1, and the planarization layer PLL_1, and as such, contact holes CNT may be omitted from planarization layer PLL_1, thereby simplifying the structure and omitting one or more manufacturing processes.

An anisotropic conductive film ACF may be formed along stepped portions of the first upper pad electrodes PCE1_1 and may be bent by a process of compression bonding the anisotropic conductive film ACF to the first circuit board CB1. The first circuit board CB1 may also be bent along the stepped portions of the first upper pad electrodes PCE1_1.

The second upper pad electrodes PCE2_1 may be disposed on the first panel pads PD1 and may not overlap the second panel pads PD2 in the third direction DR3. The second upper pad electrodes PCE2_1 may be disposed on (e.g., directly on) the first panel pads PD1 and the first insulating layer INS1. The second upper pad electrodes PCE2_1 may not overlap the planarization layer PLL_1 in the third direction DR3.

As described above, at least because the planarization layer PLL_1 is formed not to overlap the first panel pads PD1 in the third direction DR3 and to overlap the second panel pads PD2 in the third direction DR3, it is possible to omit the contact holes CNT in the planarization layer PLL_1, thereby simplifying the structure and omitting one or more manufacturing processes.

A method of manufacturing the display device 10 will now be described. The following description will focus on the first panel pad area PDA1 corresponding to the structure described in association with FIG. 5.

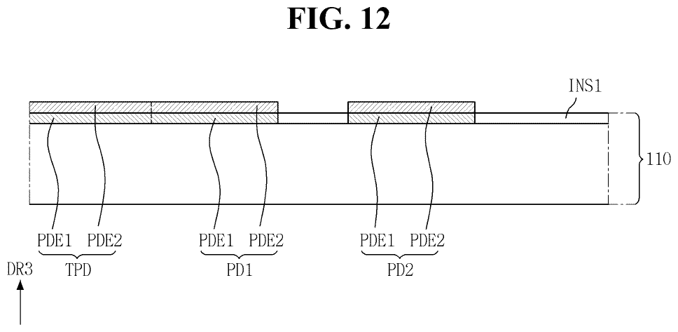

FIGS. 12 through 18 are schematic cross-sectional views of the display device 10 at various stages of manufacture according to an embodiment, and will be utilized to describe a method of manufacturing the display device 10 according to an embodiment.

Referring to FIG. 12, a first panel pad PD1, a second panel pad PD2, and a test pad TPD may be formed on a backplane substrate 110.

Each of the first panel pad PD1, the second panel pad PD2, and the test pad TPD may be formed to include a first pad electrode PDE1 and a second pad electrode PDE2. For example, the first pad electrode PDE1 may be formed through a same process as a first common connection electrode CCE1 (see FIG. 2). However, embodiments are not limited to this example, and the first pad electrode PDE1 may be formed through a separate (or different) process from the process of forming the first common connection electrode CCE1. A first insulating layer INS1 may be formed on the backplane substrate 110 and may expose the first pad electrode PDE1. The process of exposing the first pad electrode PDE1 may be performed through a CMP process.

The second pad electrode PDE2 may be formed through a same process as a second common connection electrode CCE2 (see FIG. 2). However, embodiments are not limited to this example, and the second pad electrode PDE2 may be formed through a separate (or different) process from the process of forming the second common connection electrode CCE2. The second panel pad PD2 may be electrically connected to the first panel pad PD1, but as shown in FIG. 12, the second panel pad PD2 may function as a dummy panel pad and may be spaced apart from the first panel pad PD1 in a view in the third direction DR3. In some implementations, the test pad TPD may extend from the first panel pad PD1.

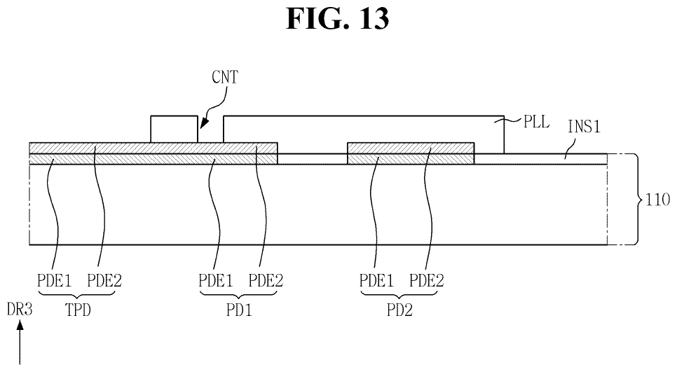

Referring to FIG. 13, a planarization layer PLL may be formed on the first panel pad PD1 and the second panel pad PD2. The planarization layer PLL may be made of an organic material. However, embodiments are not limited to this example, and the planarization layer PLL may be additionally or alternatively made of an inorganic material.

A contact hole CNT exposing a portion of the first panel pad PD1 may be formed in the planarization layer PLL. The contact hole CNT may be formed through a photo process, e.g., a photolithographic process. As the contact hole CNT is formed, a portion of the second pad electrode PDE2 of the first panel pad PD1 may be exposed.

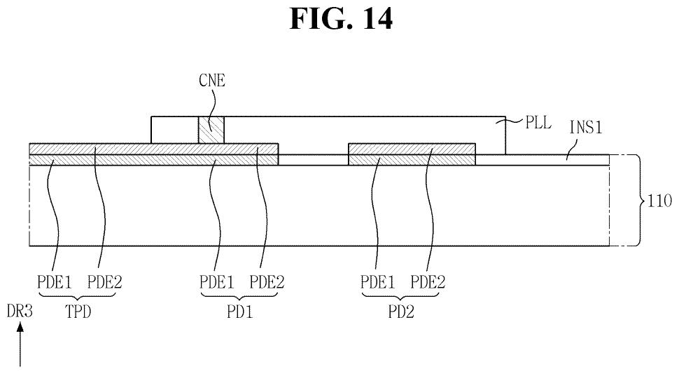

Referring to FIG. 14, a connection electrode CNE may be formed on the planarization layer PLL. The connection electrode CNE may be formed by depositing a connection electrode material on the planarization layer PLL and in the contact hole CNT and polishing the connection electrode material through a CMP process. The connection electrode CNE may be formed to fill the contact hole CNT, and a surface (e.g., an upper surface) of the connection electrode CNE may be level (or substantially level or co-planar) with a corresponding surface (e.g., a corresponding upper surface) of the planarization layer PLL. The connection electrode CNE may be electrically connected to the first panel pad PD1 through the contact hole CNT.

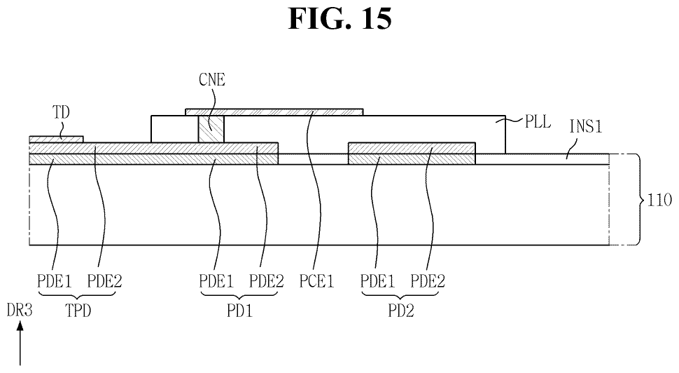

Referring to FIG. 15, a first upper pad electrode PCE1 may be formed on the planarization layer PLL, and a test electrode TD may be formed on the test pad TPD. The first upper pad electrode PCE1 and the test electrode TD may be formed by depositing a metal layer on the backplane substrate 110 and patterning the metal layer through a photo process, such as a photolithographic process.

The first upper pad electrode PCE1 may be formed on (e.g., directly on) the connection electrode CNE and may be electrically connected to the first panel pad PD1 through the connection electrode CNE. The test electrode TD may be formed on (e.g., directly on) the test pad TPD and may be electrically connected to the test pad TPD. A driving test of a display panel may be performed using the test pad TPD and a test jig. The test pad TPD may be electrically and physically connected directly to the first panel pad PD1 to perform the driving test of the display panel, but embodiments are not limited to this example. For instance, an indirect electrical connection may be utilized between the test pad TPD and the first panel pad PD1.

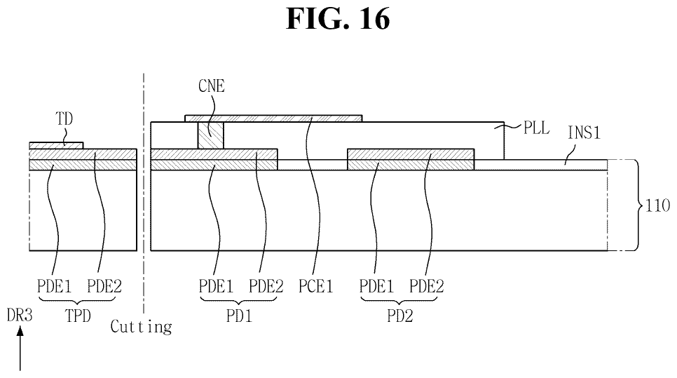

Referring to FIG. 16, after the driving test is complete, the backplane substrate 110 may be cut into cells. As part of this cutting process, the test pad TPD and test electrode TD may be cut and removed.

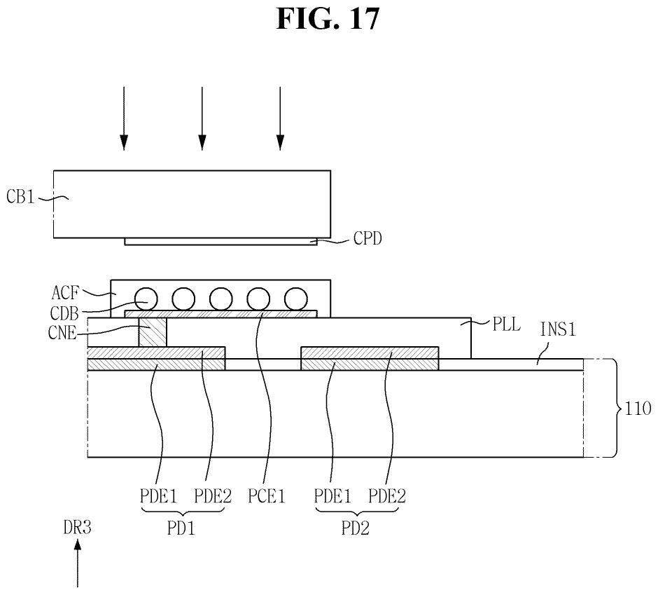

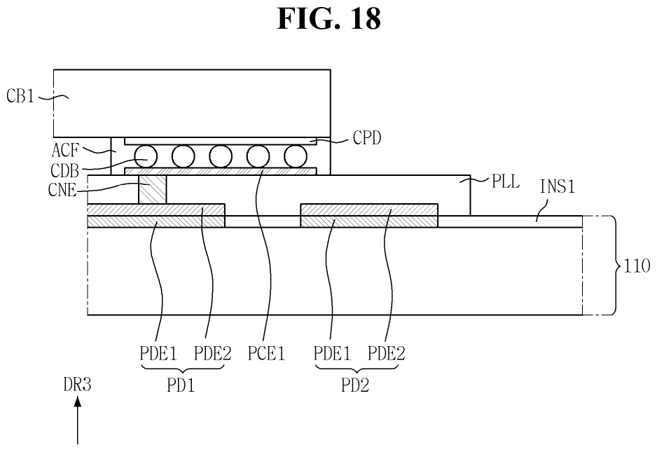

Referring to FIGS. 17 and 18, an anisotropic conductive film ACF including conductive balls CDB may be applied on the first upper pad electrode PCE1 and the planarization layer PLL. As shown in FIGS. 17 and 18, the anisotropic conductive film ACF is applied on the structure form on the backplane substrate 110. However, embodiments are not limited to this example. For instance, the anisotropic conductive film ACF may be applied on a first circuit board CB1.

The first circuit board CB1 on which a circuit pad CPD is formed may be aligned with respect to the backplane substrate 110. For example, the circuit pad CPD of the first circuit board CB1 and the first upper pad electrode PCE1 may be aligned to face each other in the third direction DR3. The first circuit board CB1 and the backplane substrate 110 may be compressed together using a thermocompression process to bond the first circuit board CB1 to the structure formed on the backplane substrate 110, e.g., to the first upper pad electrode PCE1. The first upper pad electrode PCE1 and the circuit pad CPD of the first circuit board CB1 may be electrically connected by the conductive balls CDB of the anisotropic conductive film ACF.

According to various embodiments, a method of manufacturing a display device may include bonding a backplane substrate 110 and a first circuit board CB1 together using an anisotropic conductive film ACF, which may include conductive balls CDB. At least because a bonding method using an anisotropic conductive film ACF may be applied in association with forming a relatively high-resolution display device rather than a wire bonding method, a degree of process freedom can be increased.

Although a case in which a test pad TPD and a test electrode TD are formed is illustrated and described, embodiments are not limited to this example. For instance, the forming of the test pad TPD and the test electrode TD may be omitted.

The display devices described in association with FIGS. 9 through 11 may be manufactured by forming the planarization layer PLL_1 on the second panel pads PD2 and not on the first panel pads PD1, and as such, the process of manufacturing the contact holes CNT can be omitted. This may not only reduce the number of manufacturing processes and associated manufacturing time, but may also reduce the cost and complexity of forming an associated display device.

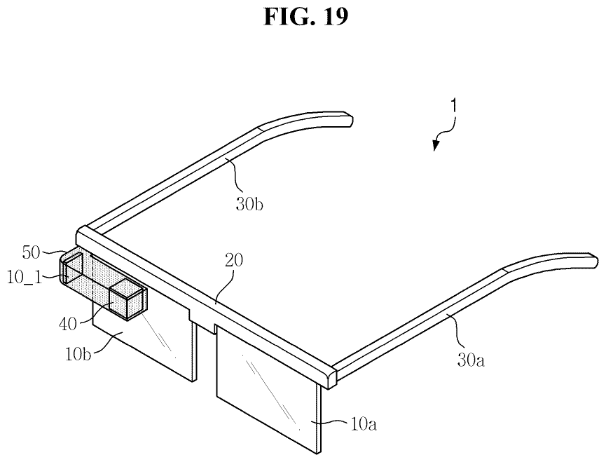

FIG. 19 is a schematic perspective view of a virtual reality (VR) device including a display device according to an embodiment.

FIG. 19 illustrates a VR device 1 to which a display device 10_1 according to an embodiment has been applied or incorporated as a portion of the VR device 1.

Referring to FIG. 19, the VR device 1 according to an embodiment may be a device in the form of glasses. The VR device 1 according to an embodiment may include the display device 10_1, a first (e.g., left) lens 10a, a second (e.g., right) lens 10b, a support frame 20, eyeglass frame legs 30a and 30b, a reflective member (or structure) 40, and a display device housing 50.

In FIG. 19, the VR device 1 including the eyeglass frame legs 30a and 30b is illustrated as an example. However, the VR device 1 according to some embodiments may be formed as a head-mounted display including a head-mounted band, which can be mounted on the head of a user, instead of the eyeglass frame legs 30a and 30b. The VR device 1 is not limited to the structure illustrated in FIG. 19 and can be applied in various forms to various other electronic devices.

The display device housing 50 may include the display device 10_1 and the reflective member 40. An image displayed on or via the display device 10_1 may be reflected by the reflective member 40 and provided to a user's right eye through the right lens 10b. The user may view a VR image displayed on the display device 10_1 through their right eye.

Although the display device housing 50 is disposed at a right end of the support frame 20 in FIG. 19, embodiments are not limited to this structure. For example, the display device housing 50 may be disposed at a left end of the support frame 20. An image displayed on the display device 10_1 may be reflected by the reflective member 40 and provided to the user's left eye through the left lens 10a. The user may view a VR image displayed on the display device 10_1 through their left eye. As another example, the display device housing 50 may be disposed at both the right end and the left end of the support frame 20. The user may view a VR image displayed on the display device 10_1 through both their left eye and their right eye.

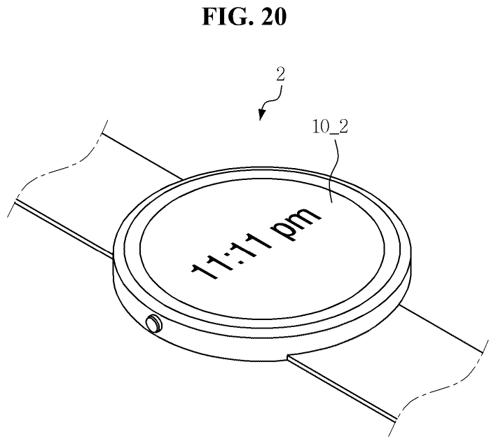

FIG. 20 is a schematic perspective view of a smart device 2 including a display device according to an embodiment.

Referring to FIG. 20, a display device 10_2 according to an embodiment may be applied to or incorporated as part of a smart watch 2, which is one type of smart device.

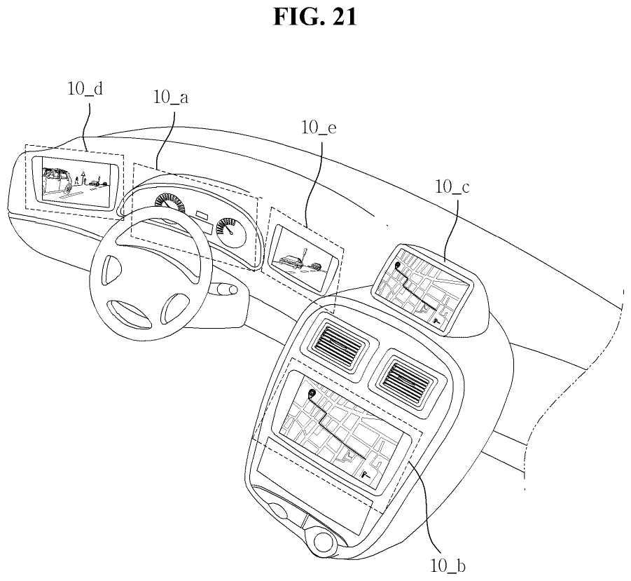

FIG. 21 is a schematic perspective view of a vehicle including a display device according to an embodiment.

FIG. 21 illustrates a vehicle to which a display device according to an embodiment has been applied or otherwise incorporated.

Referring to FIG. 21, the display device according to some embodiments may be applied to an instrument cluster 10_a of the vehicle, a center fascia 10_b of the vehicle, or center information displays (CIDs) 10_c, 10_d, and 10_e disposed on and/or incorporated in a dashboard of the vehicle. In some embodiments, the display device may be applied to one or more room (or cockpit) mirror displays that replace side mirrors and/or a rearview mirror of the vehicle.

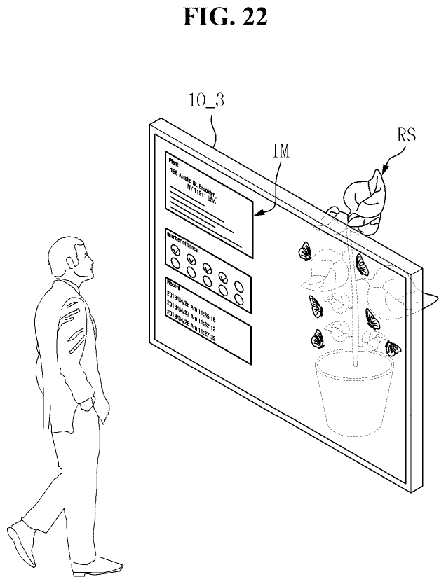

FIG. 22 is a schematic perspective view of a transparent display device including a display device according to an embodiment.

Referring to FIG. 22, a display device 10_3 according to an embodiment may be applied to or form a transparent display device. The transparent display device may transmit light while displaying an image IM. A user located in front of the transparent display device may not only view the image IM displayed on the display device 10_3, but may also view an object RS or a background located behind the transparent display device. In a case that the display device 10_3 is applied to the transparent display device, at least one layer (or member) constituting the display panel 100 described in association with FIG. 2 may include a light transmitting portion that can transmit light or may be made of a material that can transmit light.

According to various embodiments, adhesion reliability can be improved by increasing the area of adhesion between an anisotropic conductive film and an upper pad electrode forming portions of a display device. A relatively high-resolution display device in which a pad area and a circuit board are bonded together using an anisotropic conductive film can be implemented using one or more embodiments.

According to some embodiments, at least because a planarization layer may be formed not to overlap a first panel pad and to overlap a second panel pad, it is possible to omit one or more contact holes, thereby simplifying the structure of a display device and omitting one or more manufacturing processes.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered illustrative and not as restrictive, and embodiments are not to be limited to the details given herein.

What is claimed is:

1. A display device comprising:
a substrate comprising a display area and a non-display area;
a first panel pad area disposed on the non-display area;
first panel pads disposed on the first panel pad area, the first panel pads being spaced apart from one another along a first direction;
second panel pads spaced apart from the first panel pads in a second direction transverse to the first direction, the second panel pads being spaced apart from one another along the first direction;
a planarization layer disposed on the first panel pads and the second panel pads, the planarization layer comprising contact holes, each contact hole exposing a corresponding first panel pad among the first panel pads;
upper pad electrodes disposed on the planarization layer, each upper pad electrode among the upper pad electrodes being electrically connected to a corresponding first panel pad among the first panel pads via a corresponding contact hole among the contact holes;
a circuit board overlapping the first panel pad area in a third direction perpendicular to the first direction and the second direction, the circuit board comprising circuit pads; and
an anisotropic conductive film disposed on the first panel pad area and electrically connecting each upper pad electrode among the upper pad electrodes to a corresponding circuit pad among the circuit pads.

2. The display device of claim 1, wherein the upper pad electrodes comprise a first upper pad electrode and a second upper pad electrode spaced apart from the first upper pad electrode in the first direction.

3. The display device of claim 2, wherein
the first upper pad electrode overlaps one first panel pad in the third direction among the first panel pads, and
the second upper pad electrode overlaps another first panel pad in the third direction among the first panel pads, the another first panel pad being adjacent to the one first panel pad.

4. The display device of claim 3, wherein
the first upper pad electrode overlaps two second panel pads in the third direction among the second panel pads, the two second panel pads being adjacent to the one first panel pad, and
the second upper pad electrode does not overlap the second panel pads in the third direction.

5. The display device of claim 2, wherein the first upper pad electrode is disposed closer to the display area than the second upper pad electrode.

6. The display device of claim 1, wherein respective widths of the upper pad electrodes are greater than corresponding widths of the first panel pads or corresponding widths of the second panel pads.

7. The display device of claim 1, wherein the first panel pads and the upper pad electrodes are arranged in one-to-one correspondence with each other.

8. The display device of claim 1, wherein each of the upper pad electrodes comprises a first part having a first width and a second part having a second width, the first width being smaller than the second width.

9. The display device of claim 8, wherein
the upper pad electrodes comprise a first upper pad electrode and a second upper pad electrode, and
a direction in which the first part of the first upper pad electrode protrudes from the second part of the first upper pad electrode is opposite a direction in which the first part of the second upper pad electrode protrudes from the second part of the second upper pad electrode.

10. The display device of claim 9, wherein
the direction in which the first part of the first upper pad electrode protrudes from the second part of the first upper pad electrode is a direction extending toward an adjacent side of the substrate, and
the direction in which the first part of the second upper pad electrode protrudes from the second part of the second upper pad electrode is a direction extending toward the display area.

11. The display device of claim 9, wherein
the first upper pad electrode overlaps one first panel pad in the third direction among the first panel pads,
the first upper pad electrode overlaps two second panel pads in the third direction among the second panel pads, the two second panel pads being adjacent to the one first panel pad, and
the second upper pad electrode does not overlap the second panel pads in the third direction.

12. A display device comprising:
a substrate comprising a display area and a non-display area;
a first panel pad area disposed on the non-display area;
first panel pads disposed on the first panel pad area, the first panel pads being spaced apart from one another along a first direction;
second panel pads spaced apart from the first panel pads in a second direction transverse to the first direction, the second panel pads being spaced apart from one another along the first direction;
a planarization layer disposed on the second panel pads;
upper pad electrodes disposed on the first panel pads;
a circuit board overlapping the first panel pad area in a third direction perpendicular to the first direction and the second direction, the circuit board comprising circuit pads; and
an anisotropic conductive film disposed on the first panel pad area and electrically connecting each upper pad electrode among the upper pad electrodes to a corresponding circuit pad among the circuit pads.

13. The display device of claim 12, wherein the planarization layer overlaps the second panel pads in the third direction and does not overlap the first panel pads in the third direction.

14. The display device of claim 12, wherein each of the upper pad electrodes directly contacts a corresponding first panel pad among the first panel pads.

15. The display device of claim 12, wherein the upper pad electrodes comprise a first upper pad electrode and a second upper pad electrode spaced apart from the first upper pad electrode in the first direction.

16. The display device of claim 15, wherein
the first upper pad electrode overlaps the planarization layer in the third direction, and
the second upper pad electrode does not overlap the planarization layer in the third direction.

17. A method of manufacturing a display device, the method comprising:
forming, on a substrate,
first panel pads spaced apart from one another along a first direction, and
second panel pads spaced apart from the first panel pads in a second direction transverse to the first direction, the second panel pads being spaced apart from one another along the first direction;
forming a planarization layer on the second panel pads or both the first panel pads and the second panel pads;
forming upper pad electrodes on at least the planarization layer, each the upper pad electrodes among the upper pad electrodes being electrically connected to a corresponding first panel pad among the first panel pads;
aligning circuit pads of a circuit board with the upper pad electrodes; and
compressing an anisotropic conductive film between the circuit board and the substrate to bond the circuit board and the substrate together and to form respective electrical connections between the upper pad electrodes and the circuit pads.

18. The method of claim 17, wherein
the planarization layer is formed on both the first panel pads and the second panel pads,
the method further comprises:
forming contact holes in the planarization layer, each contact hole among the contact holes exposing a corresponding first panel pad among the first panel pads; and
forming connection electrodes in the contact holes, each connection electrode being formed in a corresponding contact hole among the contact holes, and
each upper pad electrode among the upper pad electrodes is electrically connected to a corresponding first panel pad among the first panel pads through a corresponding connection electrode among the connection electrodes.

19. The method of claim 17, wherein
in a view in a third direction perpendicular to the first direction and the second direction, the planarization layer does not overlap the first panel pads,
each upper pad electrode among the upper pad electrodes is further formed directly on a portion of a corresponding first panel pad among the first panel pads to form an electrical connection between that upper pad electrode and the corresponding first panel pad.

20. The method of claim 17, further comprising:
forming, on the substrate, test pads from a same layer of material used to form the first panel pads, each test pad being electrically connected to a corresponding first panel pad among the first panel pads;
forming test electrodes on the test pads from a same layer of material used to form the upper pad electrodes; and
cutting the substrate into at least one cell,
wherein cutting the substrate into the at least one cell separates the test pads and the test electrodes from the display device.
